(19) United States
(12) Patent Application Publication
(10) Pub. No.: US 2026/0164688 A1
(43) Pub. Date: Jun. 11, 2026

(54) SEMICONDUCTOR APPARATUS AND METHOD FOR MANUFACTURING THE SAME

(71) Applicant: Mitsubishi Electric Corporation, Tokyo (JP)

(72) Inventors: Sho TANAKA, Tokyo (JP); Tatsuo HARADA, Tokyo (JP)

(73) Assignee: Mitsubishi Electric Corporation, Tokyo (JP)

(21) Appl. No.: 19/388,768

(22) Filed: Nov. 13, 2025

(30) Foreign Application Priority Data
Dec. 6, 2024 (JP) 2024-213246

(51) Int. Cl. H10D 12/00; H03K 17/14; H10D 12/01; H10D 62/60

(52) U.S. Cl. CPC H10D 12/481; H03K 17/14; H10D 12/038; H10D 62/60; H03K 2217/0036; H03K 2217/0081

(57) ABSTRACT

A semiconductor apparatus comprises a bipolar transistor. The bipolar transistor includes a semiconductor substrate having a first surface and a second surface, and a first electrode provided on the first surface. The semiconductor substrate includes a drift layer, a body layer, a charge accumulation region, and a source region and a contact region. The bipolar transistor further includes at least one first trench gate and a plurality of second trench gates extending from the first surface toward the second surface. The semiconductor substrate between adjacent ones of the plurality of second trench gates includes the body layer, the contact region, and a first region located between the body layer and the contact region and having an impurity density lower than that of the body layer.

### CROSS REFERENCE TO RELATED APPLICATIONS

This nonprovisional application is based on Japanese Patent Application No. 2024-213246 filed on Dec. 6, 2024 with the Japan Patent Office, the entire contents of which are hereby incorporated by reference.

### BACKGROUND OF THE INVENTION

### Field of the Invention

The present disclosure relates to a semiconductor apparatus and a method for manufacturing the same.

### Description of the Background Art

A known bipolar transistor comprises a p-type collector layer, an n-type drift layer, a p-type body layer, an n-type charge accumulation region and a p-type channel doped layer, and is provided with a trench gate penetrating the body layer, the charge accumulation region and the channel doped layer and reaching the drift layer (see, for example, Japanese Patent Laying-Open No. 2009-253004). When such a bipolar transistor is in the on state, the pn junction between the charge accumulation region and the channel doped layer suppresses discharging to the channel doped layer of holes injected from the p-type collector layer into the n-type drift layer, and thus contributes to suppression of conduction loss.

### SUMMARY OF THE INVENTION

According to the present disclosure, a semiconductor apparatus comprises a bipolar transistor. The bipolar transistor includes a semiconductor substrate having a first surface and a second surface opposite to the first surface, and a first electrode provided on the first surface. The semiconductor substrate includes a drift layer, a body layer located closer to the first surface than the drift layer is, a charge accumulation region located on the body layer, and a source region and a contact region formed in the first surface and electrically connected to the first electrode. The bipolar transistor further includes at least one first trench gate and a plurality of second trench gates extending from the first surface toward the second surface. The plurality of second trench gates are each smaller in depth from the first surface than the at least one first trench gate is. The at least one first trench gate penetrates the source region, the charge accumulation region, and the body layer to reach the drift layer. The plurality of second trench gates are spaced from and adjacent to one another. The semiconductor substrate between adjacent ones of the plurality of second trench gates includes the body layer, the contact region, and a first region located between the body layer and the contact region and having an impurity density lower than that of the body layer.

The foregoing and other objects, features, aspects and advantages of the present invention will become apparent from the following detailed description of the present invention when taken in conjunction with the accompanying drawings.

### BRIEF DESCRIPTION OF THE DRAWINGS

FIG. 1 is a schematic plan view of an example of a semiconductor apparatus according to a first embodiment.

FIG. 2 is a schematic plan view showing a region II shown in FIG. 1.

FIG. 3 is a schematic cross section taken along a cross-sectional line III-III indicated in FIG. 2.

FIG. 4 is a flowchart of an example of a method for manufacturing the semiconductor apparatus according to the first embodiment.

FIG. 5 is a schematic cross section for illustrating one step of the method for manufacturing the semiconductor apparatus according to the first embodiment.

FIG. 6 is a schematic cross section for illustrating one step after the step shown in FIG. 5 in the method for manufacturing the semiconductor apparatus according to the first embodiment.

FIG. 7 is a schematic cross section for illustrating one step after the step shown in FIG. 6 in the method for manufacturing the semiconductor apparatus according to the first embodiment.

FIG. 8 is a schematic cross section for illustrating one step after the step shown in FIG. 7 in the method for manufacturing the semiconductor apparatus according to the first embodiment.

FIG. 9 is a schematic cross section for illustrating one step after the step shown in FIG. 8 in the method for manufacturing the semiconductor apparatus according to the first embodiment.

FIG. 10 is a schematic cross section of a variation of the semiconductor apparatus according to the first embodiment.

FIG. 11 represents an example of a profile of an impurity density of a first region in a semiconductor apparatus according to a second embodiment.

FIG. 12 is a schematic cross section of an example of a semiconductor apparatus according to a third embodiment.

FIG. 13 plots a relationship between a spacing Wp between adjacent ones of a plurality of second trenches and the impurity density of the first region in the semiconductor apparatus according to the third embodiment.

FIG. 14 is a schematic cross section of an example of a semiconductor apparatus according to a fourth embodiment.

FIG. 15 is a schematic cross section of an example of a semiconductor apparatus according to a fifth embodiment.

FIG. 16 is a schematic cross section of an example of a semiconductor apparatus according to a sixth embodiment.

FIG. 17 is a schematic cross section of a variation of the semiconductor apparatus according to the sixth embodiment.

FIG. 18 is a schematic cross section of an example of a semiconductor apparatus according to a seventh embodiment.

FIG. 19 is a schematic cross section for illustrating one step of a method for manufacturing the semiconductor apparatus according to the seventh embodiment.

FIG. 20 is a schematic cross section for illustrating one step after the step shown in FIG. 19 in the method for manufacturing the semiconductor apparatus according to the seventh embodiment.

FIG. 21 is a schematic cross section for illustrating one step after the step shown in FIG. 20 in the method for manufacturing the semiconductor apparatus according to the seventh embodiment.

FIG. 22 is a schematic cross section for illustrating one step in a first variation of the method for manufacturing the semiconductor apparatus according to the seventh embodiment.

FIG. 23 is a schematic cross section for illustrating one step after the step shown in FIG. 22 in the first variation of the method for manufacturing the semiconductor apparatus according to the seventh embodiment.

FIG. 24 is a schematic cross section for illustrating one step after the step shown in FIG. 23 in the first variation of the method for manufacturing the semiconductor apparatus according to the seventh embodiment.

FIG. 25 is a schematic cross section for illustrating one step in a second variation of the method for manufacturing the semiconductor apparatus according to the seventh embodiment.

FIG. 26 is a schematic cross section for illustrating one step after the step shown in FIG. 25 in the second variation of the method for manufacturing the semiconductor apparatus according to the seventh embodiment.

FIG. 27 is a schematic cross section for illustrating one step after the step shown in FIG. 26 in the second variation of the method for manufacturing the semiconductor apparatus according to the seventh embodiment.

FIG. 28 is a schematic cross section for illustrating one step after the step shown in FIG. 27 in the second variation of the method for manufacturing the semiconductor apparatus according to the seventh embodiment.

FIG. 29 is a schematic cross section of an example of a semiconductor apparatus according to an eighth embodiment.

FIG. 30 is a schematic cross section for illustrating one step of a method for manufacturing the semiconductor apparatus according to the eighth embodiment.

FIG. 31 plots a relationship between a width of an opening of a trench mask and a depth of a trench formed by selectively etching the semiconductor substrate through the trench mask in the method for manufacturing the semiconductor apparatus according to the eighth embodiment.

FIG. 32 is a schematic cross section of an example of a semiconductor apparatus according to a ninth embodiment.

FIG. 33 is a schematic plan view of the example of the semiconductor apparatus according to the ninth embodiment.

FIG. 34 is a waveform diagram for illustrating an exemplary operation of the semiconductor apparatus according to the ninth embodiment.

FIG. 35 shows a result of an evaluation of voltage applied to a trench gate and conduction loss in examples of the semiconductor apparatus according to the ninth embodiment and comparative examples.

FIG. 36 is a waveform diagram for illustrating an exemplary operation of a semiconductor apparatus according to a tenth embodiment.

FIG. 37 shows a result of an evaluation of a first time difference t_{off1} and a switching loss E_{off} at a time of turning off in examples of the semiconductor apparatus according to the tenth embodiment and comparative examples.

FIG. 38 shows a result of an evaluation of a second time difference tₒₙ₁ and a switching loss Eₒₙ at a time of turning on in examples of the semiconductor apparatus according to the tenth embodiment and comparative examples.

FIG. 39 is a waveform diagram for illustrating an exemplary operation of a semiconductor apparatus according to an eleventh embodiment.

FIG. 40 shows a result of an evaluation of a third voltage V_{dpoff} and the switching loss E_{off} at the time of turning off in examples of the semiconductor apparatus according to the eleventh embodiment and comparative examples.

FIG. 41 shows a result of an evaluation of a fourth voltage V_{dpon} and the switching loss Eₒₙ at the time of turning on in examples of the semiconductor apparatus according to the eleventh embodiment and comparative examples.

### DESCRIPTION OF THE PREFERRED EMBODIMENTS

Hereinafter, embodiments of the present disclosure will be described with reference to the drawings. In the following description, identical or equivalent components are identically denoted and will not be described repeatedly.

### First Embodiment

### <Configuration of Semiconductor Apparatus>

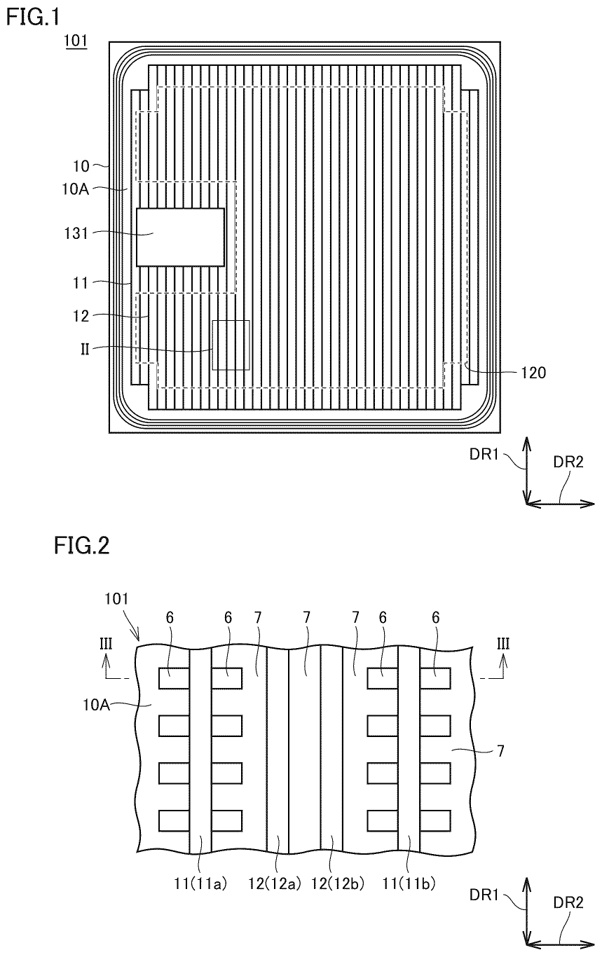

An example of a semiconductor apparatus 101 according to a first embodiment will now be described with reference to FIGS. 1 to 3. Semiconductor apparatus 101 comprises a bipolar transistor as a semiconductor device. The bipolar transistor has a trench gate. The bipolar transistor is, for example, an insulated gate bipolar transistor (IGBT) having a trench gate.

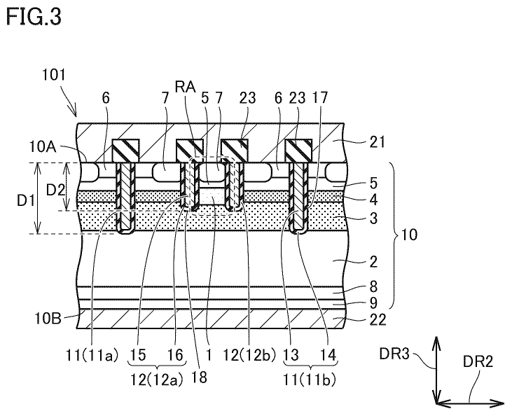

Semiconductor apparatus 101 comprises a semiconductor substrate 10, a first electrode 21 (see FIG. 3), and a second electrode 22 (see FIG. 3). Semiconductor substrate 10 has a first surface 10A and a second surface 10B (see FIG. 3) located on a side opposite to first surface 10A. While semiconductor substrate 10 may be formed of any material, it is formed for example of silicon (Si) or silicon carbide (SiC). FIGS. 1 and 2 are plan views of semiconductor apparatus 101 as viewed on the side of first surface 10A of semiconductor substrate 10. FIGS. 1 and 2 do not show first electrode 21.

As shown in FIG. 1, in a plan view on the side of first surface 10A, semiconductor substrate 10 includes a device region 120 and an outer peripheral region surrounding device region 120. In device region 120 is formed a bipolar transistor having a first trench gate 11 and a second trench gate 12. First trench gate 11 and second trench gate 12 extend in a first direction DR1 along first surface 10A and are spaced from each other in a second direction DR2 along first surface 10A and orthogonal to first direction DR1. First trench gate 11 and second trench gate 12 are each electrically connected to a gate pad 131. Semiconductor apparatus 101 has first trench gate 11 and second trench gate 12 provided so that equal voltage is applied thereto with the same timing via gate pad 131.

As shown in FIGS. 1 to 3, semiconductor apparatus 101 comprises a plurality of first trench gates 11 and a plurality of second trench gates 12. The plurality of first trench gates 11 and the plurality of second trench gates 12 extend in first direction DR1 in parallel to each other.

As shown in FIGS. 2 and 3, the plurality of first trench gates 11 include a first first trench gate 11a and a second first trench gate 11b. First first trench gate 11a and second first trench gate 11b are spaced from and adjacent to each other in the plurality of first trench gates 11. The plurality of second trench gates 12 include a first second trench gate 12a and a second second trench gate 12b. First second trench gate 12a and second second trench gate 12b are spaced from and adjacent to each other in the plurality of second trench gates 12. First first trench gate 11a, first second trench gate 12a, second second trench gate 12b, and second first trench gate 11b are aligned in this order in second direction DR2. First first trench gate 11a and second first trench gate 11b are disposed so as to sandwich first second trench gate 12a and second second trench gate 12b in second direction DR2.

As shown in FIG. 3, semiconductor substrate 10 includes a first region 1, a drift layer 2, a body layer 3, a charge accumulation region 4, a channel doped layer 5, a source region 6 (an emitter region), a contact region 7, a buffer layer 8, and a collector layer 9.

Drift layer 2, charge accumulation region 4, and buffer layer 8 are of a first conduction type. Body layer 3, channel doped layer 5, contact region 7, and collector layer 9 are of a second conduction type. First region 1 is for example of the second conduction type. For example, the first conduction type is n-type and the second conduction type is p-type. The first conduction type may be the p-type, and the second conduction type may be the n-type.

Source region 6 has a first conduction type impurity density higher than that of charge accumulation region 4. Channel doped layer 5 has a second conduction type impurity density higher than that of body layer 3 and lower than that of contact region 7. First region 1 has a second conduction type impurity density lower than that of body layer 3.

First region 1 may have the second conduction type impurity density in any profile in a third direction DR3 intersecting first surface 10A. First region 1 may have the second conduction type impurity density fixed regardless of the location in third direction DR3.

Body layer 3 is located closer to first surface 10A than drift layer 2 is. Body layer 3 is in contact with drift layer 2. First region 1 and charge accumulation region 4 are each located closer to first surface 10A than body layer 3 is. First region 1 and charge accumulation region 4 are each in contact with body layer 3. First region 1 and charge accumulation region 4 are adjacent to each other in second direction DR2 with second trench gate 12 interposed therebetween.

Channel doped layer 5 is located closer to first surface 10A than first region 1 and charge accumulation region 4 are. Channel doped layer 5 is in contact with each of first region 1 and charge accumulation region 4. Source region 6 and contact region 7 are formed in first surface 10A. Source region 6 is formed in a portion of first surface 10A. Contact region 7 is formed in another portion of first surface 10A. Source region 6 and contact region 7 are each in contact with channel doped layer 5.

Buffer layer 8 is located closer to second surface 10B than drift layer 2 is. Buffer layer 8 is in contact with drift layer 2. Collector layer 9 is formed in second surface 10B. Collector layer 9 is in contact with buffer layer 8.

As shown in FIG. 3, the plurality of first trench gates 11 and the plurality of second trench gates 12 extend from first surface 10A of semiconductor substrate 10 toward second surface 10B of the semiconductor substrate. The plurality of second trench gates 12 each have a depth D2 from first surface 10A and the plurality of first trench gates 11 each have a depth D1 from first surface 10A, depth D2 being smaller than depth D1. The plurality of first trench gates 11 each penetrate source region 6, charge accumulation region 4 and body layer 3 and reach drift layer 2. The plurality of second trench gates 12 each penetrate channel doped layer 5 and separate first region 1 and charge accumulation region 4 from each other. Preferably, the plurality of second trench gates 12 each reach body layer 3.

The plurality of first trench gates 11 are each disposed in a first trench 17 formed in semiconductor substrate 10. The plurality of first trench gates 11 each include an electrode portion 13 and an insulating film 14 in first trench 17. Insulating film 14 is formed on an internal wall surface (a bottom surface and a side surface) of first trench 17. Electrode portion 13 fills a space in first trench 17 inner than insulating film 14. The plurality of first trenches 17 each penetrate source region 6, charge accumulation region 4 and body layer 3 and reach drift layer 2. The plurality of first trenches 17 each have a bottom in drift layer 2.

The plurality of second trench gates 12 are each disposed in a second trench 18 formed in semiconductor substrate 10. The plurality of second trench gates 12 each include an electrode portion 15 and an insulating film 16 in second trench 18. Insulating film 16 is formed on an internal wall surface (a bottom surface and a side surface) of second trench 18. Electrode portion 15 fills a space in second trench 18 inner than insulating film 16. Electrode portions 13 and 15 are formed for example of polysilicon. Insulating films 14 and 16 are formed for example of silicon oxide (SiO₂). The plurality of second trenches 18 each penetrate channel doped layer 5 and separate first region 1 and charge accumulation region 4 from each other. Preferably, the plurality of second trenches 18 each have a bottom located closer to second surface 10B than a junction interface between charge accumulation region 4 and body layer 3 is.

First trench 17 has an opening having a width in second direction DR2, and the plurality of second trenches 18 may each have an opening having a width in second direction DR2 equal to that of the opening of the first trench in the second direction.

Semiconductor substrate 10 includes a region RA sandwiched between adjacent ones of the plurality of second trench gates 12. In region RA are disposed body layer 3, first region 1, channel doped layer 5, and contact region 7 in this order in third direction DR3 orthogonal to first surface 10A from a side closer to second surface 10B toward the side of first surface 10A. First region 1 is formed in semiconductor substrate 10 only at region RA. First region 1 is not formed in a region sandwiched between first trench gate 11 and second trench gate 12.

In a region sandwiched between first first trench gate 11a and first second trench gate 12a adjacent to each other are disposed body layer 3, charge accumulation region 4, channel doped layer 5, and source region 6 or contact region 7 in this order in third direction DR3 orthogonal to first surface 10A from a side closer to second surface 10B toward the side of first surface 10A.

First electrode 21 is disposed on first surface 10A of semiconductor substrate 10. First electrode 21 is electrically connected to source region 6 and contact region 7. First electrode 21 is electrically insulated from first trench gate 11 and second trench gate 12 by an interlayer insulating film 23. Interlayer insulating film 23 covers electrode portions 13 and 15 of first trench gate 11 and second trench gate 12, respectively. Second electrode 22 is disposed on second surface 10B of semiconductor substrate 10. Second electrode 22 is electrically connected to collector layer 9.

As shown in FIG. 2, a plurality of source regions 6 are formed in semiconductor substrate 10. The plurality of source regions 6 are disposed for example so as to sandwich first trench gate 11 in second direction DR2. The plurality of source regions 6 are spaced from one another in first direction DR1 for example. Contact region 7 is formed for example throughout a region free of source region 6, first trench gate 11, and second trench gate 12 for example. The arrangement of source region 6 and contact region 7 shown in FIG. 2 is only an example rather than exclusive. Source region 6 may be disposed as desired insofar as it is in contact with at least one side surface of first trench gate 11 in second direction DR2. Contact region 7 may not be formed throughout the region free of source region 6, first trench gate 11, and second trench gate 12.

### <Method for Manufacturing Semiconductor Apparatus>

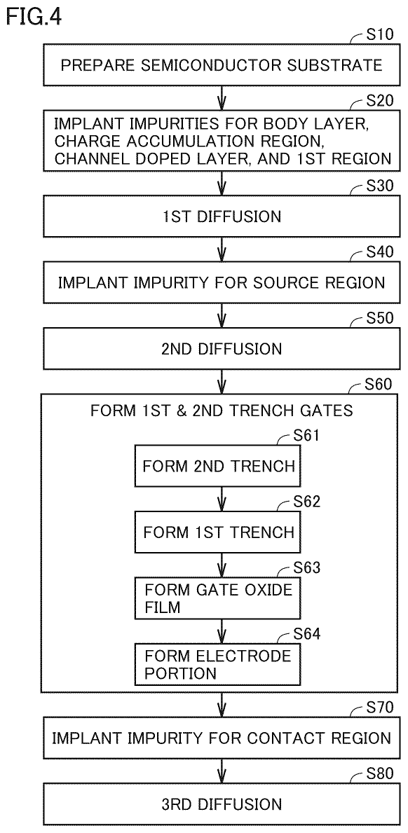

An example of a method for manufacturing semiconductor apparatus 101 will now be described with reference to FIGS. 4 to 9. FIGS. 4 to 9 are diagrams for illustrating a method for forming a structure on the side of first surface 10A in the method for manufacturing semiconductor apparatus 101.

In the method for manufacturing semiconductor apparatus 101, a semiconductor substrate of a first conduction type is prepared (S10). The semiconductor substrate has a first conduction type impurity density equal to that of drift layer 2. The semiconductor substrate has first surface 10A and second surface 10B.

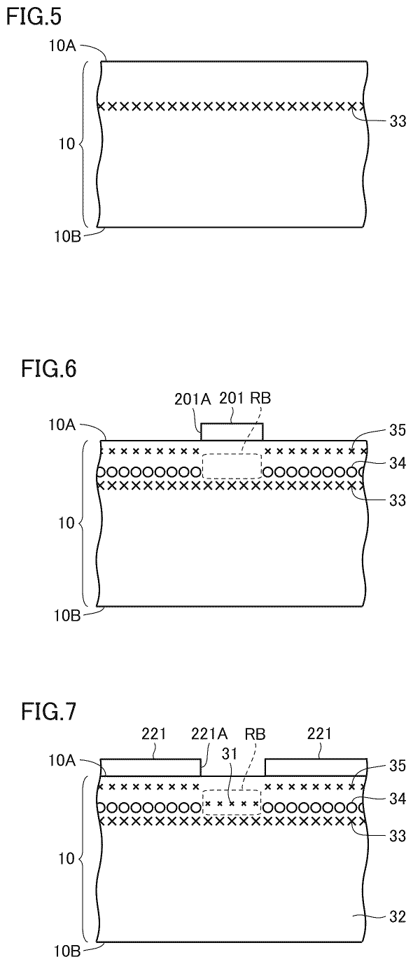

After step S10, impurities are implanted from first surface 10A of the semiconductor substrate for forming body layer 3, charge accumulation region 4, channel doped layer 5, and first region 1 (S20). As shown in FIG. 5, in the step (S20), initially, a second conduction type impurity 33 is implanted into semiconductor substrate 10 without using a mask for forming body layer 3. Subsequently, as shown in FIG. 6, a mask 201 is formed on first surface 10A to cover a region RB in which first region 1 is to be formed. Mask 201 has an opening 201A that opens on a region in which charge accumulation region 4 is to be formed. Subsequently, a first conduction type impurity 34 and a second conduction type impurity 35 are implanted into semiconductor substrate 10 successively through mask 201 for forming charge accumulation region 4 and channel doped layer 5, respectively. Subsequently, mask 201 is removed from first surface 10A. Subsequently, as shown in FIG. 7, a mask 221 having an opening 221A that opens on region RB in which first region 1 is to be formed is formed on first surface 10A. Mask 211 covers the region in which charge accumulation region 4 is to be formed. Subsequently, a second conduction type impurity is implanted into region RB of semiconductor substrate 10 through mask 221 for forming first region 1.

As has been discussed above, semiconductor apparatus 101 may have first region 1 of the first conduction type. In that case, in this step (S20), implanting the first conduction type impurity into region RB of semiconductor substrate 10 via mask 221 for forming first region 1 suffices.

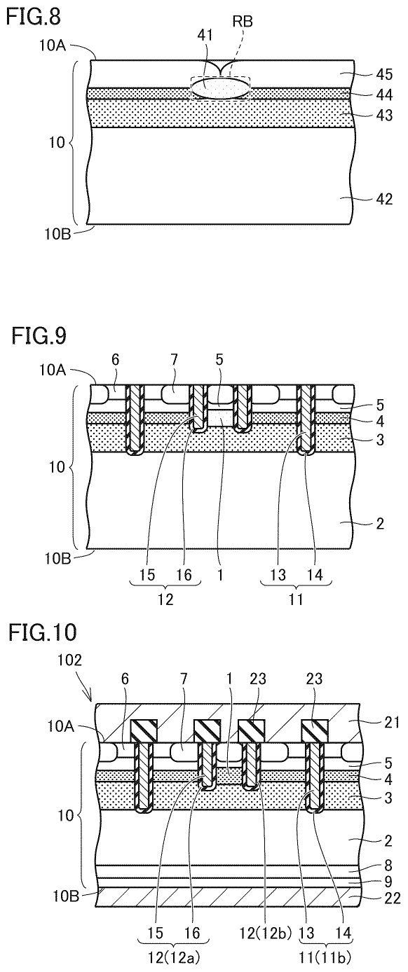

After the step (S20), semiconductor substrate 10 is heated to diffuse in semiconductor substrate 10 the impurities implanted in the step (S20) (S30). Thus, as shown in FIG. 8, impurity regions 41, 43, 44, and 45 corresponding to first region 1, body layer 3, charge accumulation region 4, and channel doped layer 5, respectively, are formed in semiconductor substrate 10. A region of semiconductor substrate 10 free of impurity regions 41, 43, 44, and 45 will be an impurity region 42 corresponding to drift layer 2.

After the step (S30), a first conduction type impurity is implanted into semiconductor substrate 10 for forming source region 6 (S40). In this step (S40), a mask is used to cover first region 1. After the step (S40), semiconductor substrate 10 is heated to diffuse in semiconductor substrate 10 the impurity implanted in the step (S30) (S50).

After the step (S50), first trench gate 11 and second trench gate 12 are formed in semiconductor substrate 10 (S60). In this step (S60), for example, second trench 18 is initially formed (S61), and first trench 17 is subsequently formed (S62). In the step (S61), second trench 18 is formed by etching a portion of semiconductor substrate 10 using a mask that opens on a region of first surface 10A in which second trench 18 is to be formed. In the step (S62), first trench 17 is formed by etching a portion of semiconductor substrate 10 using a mask that opens on a region of first surface 10A in which first trench 17 is to be formed. Insulating films 14 and 16 are formed on the bottom and side surfaces of first trench 17 and second trench 18 (S63). Insulating films 14 and 16 can be formed, for example, by oxidizing the bottom and side surfaces of first trench 17 and second trench 18. Electrode portions 13 and 15 are formed in first trench 17 and second trench 18 on insulating films 14 and 16, respectively. Electrode portions 13 and 15 can be formed, for example, by depositing a conductive film on surfaces of insulating films 14 and 16 and first surface 10A and etching back the conductive film.

After the step (S60), a second conduction type impurity is implanted in semiconductor substrate 10 for forming contact region 7 (S70). In this step (S70), a mask having an opening on first region 1 is used. After the step (S70), semiconductor substrate 10 is heated to diffuse in semiconductor substrate 10 the impurity implanted in the step (S70) (S80). Thus, as shown in FIG. 9, a structure of a stack of layers formed of body layer 3, first region 1, channel doped layer 5, and contact region 7 is formed in semiconductor substrate 10 between two adjacent second trench gates 12. Furthermore, interlayer insulating film 23 and first electrode 21 are formed on first surface 10A to form a structure on the side of second surface 10B to manufacture semiconductor apparatus 101 shown in FIG. 3.

### <Effect of Semiconductor Apparatus 101>

An effect of semiconductor apparatus 101 will now be described in comparison with a conventional bipolar transistor comprising a charge accumulation region.

As has been discussed above, when the conventional bipolar transistor is in the on state, minority carriers of holes are injected into drift layer 2 from the collector layer located on the back surface, and the charge accumulation region suppresses a decrease in a distribution in density of the holes caused as the minority carriers approach the front surface from the back surface, and the charge accumulation region thus contributes to suppression of conduction loss. However, when the conventional bipolar transistor is turned off, it is necessary to discharge a large number of the minority carriers of holes in drift layer 2 that are accumulated in the on state by the charge accumulation region, and it is difficult to suppress an increase in switching loss.

In contrast, semiconductor apparatus 101 comprises semiconductor substrate 10 including between adjacent ones of the plurality of second trench gates 12 body layer 3, contact region 7, and first region 1 located between body layer 3 and contact region 7 and having an impurity density lower than that of body layer 3. First region 1 of semiconductor apparatus 101 is identical in conduction type to body layer 3, i.e., of the same second conduction type.

In that case, when semiconductor apparatus 101 is in the on state, and a predetermined voltage approximately equal to a voltage applied to first trench gate 11 (e.g., 15 V) is also applied to each of the plurality of second trench gates 12, a depletion layer may spread from each of the plurality of second trenches 18 into first region 1. From a different viewpoint, at least a portion of first region 1 can be depleted before body layer 3 is depleted. The depletion layer formed in first region 1, as well as charge accumulation region 4, suppresses discharging of holes to channel doped layer 5 and contact region 7 and thus contributes to suppression of conduction loss.

In contrast, when semiconductor apparatus 101 is turned off, the voltage applied to second trench gate 12 is less than the predetermined voltage, and a state without a depletion layer formed in first region 1 can be implemented. When the semiconductor apparatus is turned off, first region 1 acts as a simple resistor and can serve as a path for discharging from drift layer 2 a large number of minority carriers of holes accumulated in drift layer 2 on the side of first surface 10A. Consequently, semiconductor apparatus 101 can suppress an increase in switching loss caused when the semiconductor apparatus is turned off.

Furthermore, in semiconductor apparatus 101, body layer 3 has an impurity density higher than that of first region 1 located on a partial region of body layer 3, and in region RA first region 1 alone has as low an impurity density as allowing a depletion layer to be formed when the semiconductor apparatus is in the on state. Therefore, when semiconductor apparatus 101 is compared with the above conventional bipolar transistor, the former can more effectively discharge holes when the semiconductor apparatus is turned off, and hence suppress an increase in switching loss.

Preferably, the plurality of second trenches 18 each have a bottom located closer to second surface 10B than the junction interface between charge accumulation region 4 and body layer 3 is. This allows holes accumulated in the on state to be discharged more effectively.

### <Variation of Semiconductor Apparatus 101>

FIG. 10 is a cross section of a semiconductor apparatus 102 that is a variation of semiconductor apparatus 101. As shown in FIG. 10, first region 1 may be of the first conduction type. First region 1 may be of a conduction type different from that of body layer 3 and channel doped layer 5. In that case, a pnp structure is formed in region RA. A depletion layer of a pn junction interface in region RA is formed in the on state when a voltage equal to or larger than a predetermined voltage is applied to each of the plurality of second trench gates 12. This depletion layer suppresses discharging of holes to channel doped layer 5 and thus contributes to suppression of conduction loss. When a voltage also applied to each of the plurality of second trench gates 12 at the time of turning off becomes less than the predetermined voltage, a p-type channel is formed in first region 1 along second trench 18, and holes accumulated in the on state are discharged to channel doped layer 5 via the p-type channel. Note that the predetermined voltage varies depending on the conduction type of first region 1.

### Second Embodiment

A semiconductor apparatus according to a second embodiment is identical in configuration as well as function and effect to the first embodiment unless otherwise specified. Accordingly, any configuration identical to that of the first embodiment will identically be denoted and will not be described repeatedly.

FIG. 11 represents a profile of an impurity density of the first region in third direction DR3 in the semiconductor apparatus according to the second embodiment. In FIG. 11, the axis of abscissas represents depth in first region 1 from first surface 10A in third direction DR3 and the axis of ordinates represents impurity density of first region 1. As shown in FIG. 11, the semiconductor apparatus according to the second embodiment is different from semiconductor apparatus 101 in that first region 1 has an impurity density profile with a local minimum in third direction DR3 intersecting first surface 10A. From a different viewpoint, the semiconductor apparatus according to the second embodiment has first region 1 having an impurity density profile with a slope.

The impurity density profile of first region 1 has a portion indicating the local minimum and a portion indicating a value larger than the local minimum. A depth from first surface 10A of the portion exhibiting the local minimum in the impurity density profile of first region 1 can be set as desired. The portion in first region 1 with the impurity density exhibiting the local minimum may be provided at any location in third direction DR3 between an interface of first region 1 closer to first surface 10A an interface of the first region closer to second surface 10B. For example, as indicated in FIG. 11 by a line L1, the portion in first region 1 with the impurity density exhibiting the local minimum may be provided in third direction DR3 between the interface of first region 1 closer to first surface 10A and the interface of the first region closer to second surface 10B. As indicated in FIG. 11 by a line L2, first region 1 may have an impurity density exhibiting a local minimum at the interface thereof closer to first surface 10A. The first region may have an impurity density gradually increasing from the side of first surface 10A toward the side of second surface 10B. As indicated in FIG. 11 by a line L3, first region 1 may have an impurity density exhibiting a local minimum at the interface thereof closer to second surface 10B. The first region may have an impurity density gradually decreasing from the side of first surface 10A toward the side of second surface 10B.

The semiconductor apparatus according to the second embodiment can have a depletion layer formed in the on state in first region 1 at a portion exhibiting an impurity density profile with a local minimum. In other words, the semiconductor apparatus according to the second embodiment allows a depth to be determined for a depletion layer formed in first region 1 in the on state, and this facilitates designing the semiconductor apparatus.

### Third Embodiment

A semiconductor apparatus according to a third embodiment is identical in configuration as well as function and effect to the first embodiment unless otherwise specified. Accordingly, any configuration identical to that of the first embodiment will identically be denoted and will not be described repeatedly.

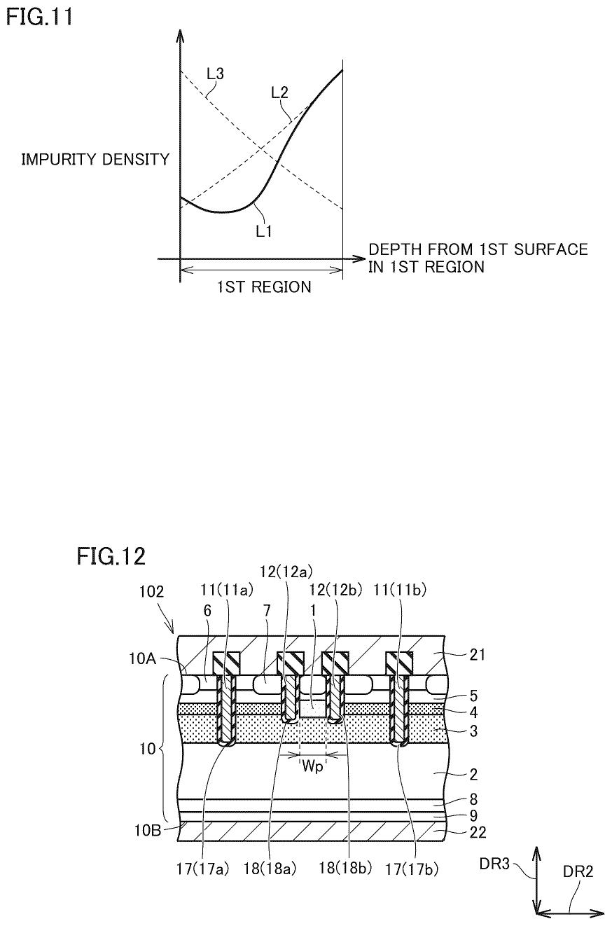

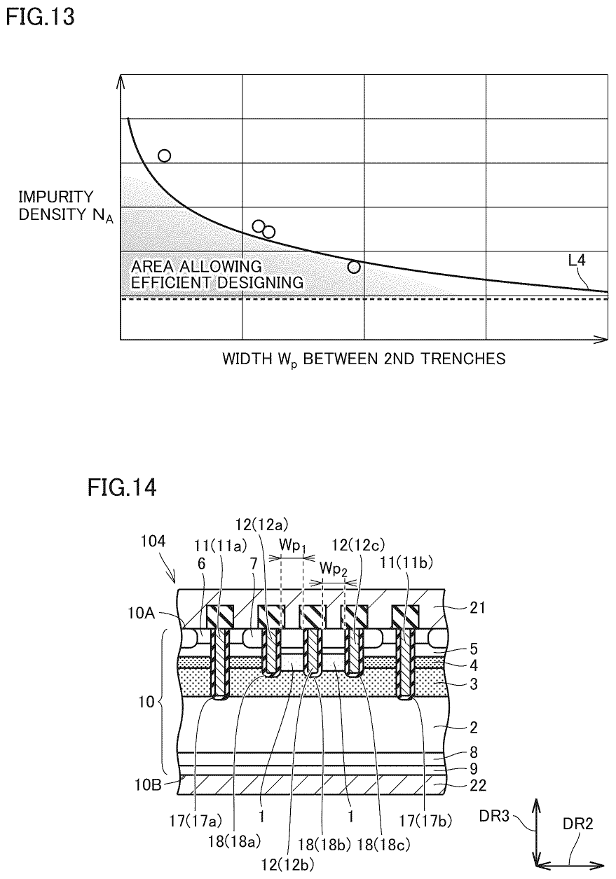

FIG. 12 is a cross section of an example of semiconductor apparatus 102 according to the third embodiment. FIG. 13 plots a relationship between a spacing Wp between adjacent ones of the plurality of second trenches 18 and an impurity density N_{A} of first region 1 in semiconductor apparatus 102. In FIG. 13, the axis of abscissas represents the spacing Wp between adjacent ones of the plurality of second trenches, and the axis of ordinates represents the impurity density N_{A} of first region 1. In FIG. 13, a line L4 represents a boundary line between a region satisfying the following relational expression (1) and a region failing to satisfy the following relational expression (1). In FIG. 13, a circular plot is a result of a simulation in which a point at which conduction loss starts to deteriorate when the spacing Wp is increased is confirmed under four conditions in which only the impurity concentration of first region 1 is varied to have values different from one another, and it shows a relationship between the impurity density of first region 1 and a width in second direction DR2 of a depletion layer formed so as to extend from each of two adjacent ones of second trench gates 12 with first region 1 interposed therebetween when a voltage of 15 V is applied to the second trench gate. In FIG. 13, a dashed line represents an impurity density of the semiconductor substrate (drift layer 2) constituting first region 1.

Semiconductor apparatus 102 is different from semiconductor apparatus 101 in that first region 1 is of the same conduction type as body layer 3, that is, of the second conduction type (e.g., the p-type), and the spacing Wp between adjacent ones of the plurality of second trenches 18 with first region 1 interposed therebetween and the impurity density N_{A} of first region 1 satisfy a relational expression (1) indicated below. Semiconductor apparatus 102 has the plurality of second trenches to have a spacing Wp therebetween satisfying the following relational expression (1):

$${W}_{p} < {\{ \frac{16 ε {k}_{B} T}{{q}^{2} {N}_{A}} ln ( \frac{{N}_{A}}{{n}_{i}} ) \}}^{\frac{1}{2}} , \qquad ( 1 )$$

where Wp represents a spacing of the plurality of second trenches 18 (unit: m), N_{A} represents an impurity density of first region 1 (unit: m⁻³), nᵢ represents an intrinsic carrier density of a semiconductor material forming first region 1 (unit: m⁻³), ε represents a dielectric constant of the semiconductor material forming first region 1, k_{B} represents a Boltzmann coefficient, T represents an absolute temperature, and q represents an elementary charge.

The spacing Wp means a maximum spacing between adjacent ones of the plurality of second trenches 18a and 18b with first region 1 interposed therebetween. For example, in a cross section orthogonal to first direction DR1, when region RA between the plurality of second trenches 18a and 18b has a cross section in a mesa, first region 1 varies in width in third direction DR3. In such a case, the spacing Wp will be equal to or larger than a maximum width of first region 1. Furthermore, when first region 1 has an impurity density profile with a local minimum, the impurity density N_{A} of first region 1 means an average value of impurity densities of a portion of first region 1 excluding contact region 7 and body layer 3.

Semiconductor apparatus 102 has the spacing Wp between adjacent ones of the plurality of second trenches and the impurity density N_{A} of first region 1 designed so as to satisfy the relational expression (1).

As shown in FIG. 13, the present inventors have confirmed that the above simulation result approximately matches the line L4, that is, that a depletion layer can be formed in first region 1 to extend between the plurality of second trenches 18 when semiconductor apparatus 102 with the spacing Wp and first region 1's impurity density N_{A} designed to satisfy the relational expression (1) is in the on state.

Semiconductor apparatus 102 allows easily designing a spacing Wp and an impurity density N_{A} for first region 1 that are necessary and sufficient for forming a depletion layer to extend between the plurality of second trenches 18 in the on state based on the relational expression (1). For example, depending on the spacing Wp between adjacent ones of the plurality of second trenches, it is possible to facilitate designing an impurity density N_{A} for first region 1 that is necessary and sufficient for forming a depletion layer to extend between the plurality of second trenches 18 in the on state. Furthermore, depending on the impurity density N_{A} of first region 1, it is possible to facilitate designing a spacing Wp necessary and sufficient for forming a depletion layer to extend between the plurality of second trenches 18 in the on state.

For semiconductor apparatus 102, a spacing between first trench 17 and second trench 18 is not particularly limited. The spacing between first trench 17 and second trench 18 may be larger than the spacing Wp. The spacing between first trench 17 and second trench 18 may be smaller than the spacing Wp.

Semiconductor apparatus 102 may be similar in configuration to the semiconductor apparatus according to the second embodiment except that first region 1 is of the same conduction type as body layer 3, that is, the second conduction type (e.g., the p-type) and the spacing Wp between adjacent ones of the plurality of second trenches 18 with first region 1 interposed therebetween and the impurity density N_{A} of first region 1 satisfy the above relational expression (1).

### Fourth Embodiment

A semiconductor apparatus according to a fourth embodiment is identical in configuration as well as function and effect to the first embodiment unless otherwise specified. Accordingly, any configuration identical to that of the first embodiment will identically be denoted and will not be described repeatedly.

FIG. 14 is a cross section of an example of a semiconductor apparatus 104 according to the fourth embodiment. As shown in FIG. 14, semiconductor apparatus 104 is different from semiconductor apparatus 101 in comprising three or more second trench gates 12 disposed between the plurality of first trench gates 11.

The plurality of second trench gates 12 include a first second trench gate 12a, a second second trench gate 12b, and a third second trench gate 12c disposed between adjacent ones of the plurality of first trench gates 11, that is, between first first trench gate 11a and second first trench gate 11b.

First first trench gate 11a is disposed in a first first trench 17a. Second first trench gate 11b is disposed in a second first trench 17b. First second trench gate 12a is disposed in a first second trench 18a. Second second trench gate 12b is disposed in a second second trench 18b. Third second trench gate 12c is disposed in a third second trench 18c.

A region between first second trench 18a and second second trench 18b and a region between second second trench 18b and third second trench 18c are equivalent to region RA of semiconductor apparatus 101 described above. Semiconductor apparatus 104 has a plurality of regions RA aligned in second direction DR2. First region 1 is formed between first second trench 18a and second second trench 18b and between second second trench 18b and third second trench 18c.

Preferably, a spacing Wp₁ between first second trench 18a and second second trench 18b and the impurity density N_{A} of first region 1 between first second trench 18a and second second trench 18b satisfy the relational expression (1). Preferably, a spacing Wp₂ between second second trench 18b and third second trench 18c and the impurity density N_{A} of first region 1 between second second trench 18b and third second trench 18c satisfy the relational expression (1). From a different viewpoint, semiconductor apparatus 104 preferably comprises three or more second trench gates 12 disposed between the plurality of first trench gates 11.

The spacing Wp₁ between first second trench 18a and second second trench 18b is for example equal to the spacing Wp₂ between second second trench 18b and third second trench 18c. The spacing Wp₁ between first second trench 18a and second second trench 18b may be different from the spacing Wp₂ between second second trench 18b and third second trench 18c.

The number of second trench gates 12 disposed between the plurality of first trench gates 11 may be any number of three or more.

A spacing between first first trench 17a and first second trench 18a is for example smaller than a sum of the spacing Wp₁ between first second trench 18a and second second trench 18b and the spacing Wp₂ between second second trench 18b and third second trench 18c.

Semiconductor apparatus 104 can suppress an increase of a spacing between first first trench 17a and first second trench 18a and that of a spacing between second first trench 17b and third second trench 18c even when there is a large spacing between first first trench 17a and second first trench 17b. When first first trench 17a and first second trench 18a have a large spacing therebetween and so do second first trench 17b and third second trench 18c, holes accumulated in a region closer to each first trench 17 than each second trench 18 are less dischargeable through first region 1. Semiconductor apparatus 104 allows holes accumulated in a region closer to each first trench 17 than each second trench 18 to be efficiently discharged through first region 1 even when there is a large spacing between first first trench 17a and second first trench 17b.

In particular, semiconductor apparatus 104 has the spacing Wp between two adjacent second trenches 18 limited so as to satisfy the relational expression (1). Accordingly, when two second trench gates 12 are disposed between the plurality of first trench gates 11, and first first trench 17a and second first trench 17b have a large spacing therebetween, first first trench 17a and first second trench 18a tend to have an increased spacing therebetween and so do second first trench 17b and third second trench 18c. Even when there is a large spacing between first first trench 17a and second first trench 17b, semiconductor apparatus 104 that has a plurality of mutually adjacent pairs of second trenches 18 with each spacing Wp therebetween satisfying the relational expression (1) allows holes accumulated in a region close to each first trench 17 to be efficiently discharged without extending a spacing between first first trench 17a and first second trench 18a and a spacing between second first trench 17b and third second trench 18c.

Semiconductor apparatus 104 may be similar in configuration to the semiconductor apparatus according to the second embodiment except that the former comprises three or more second trench gates 12 disposed between the plurality of first trench gates 11.

### Fifth Embodiment

A semiconductor apparatus according to a fifth embodiment is identical in configuration as well as function and effect to the first embodiment unless otherwise specified. Accordingly, any configuration identical to that of the first embodiment will identically be denoted and will not be described repeatedly.

FIG. 15 is a cross section of an example of a semiconductor apparatus 105 according to the fifth embodiment. As shown in FIG. 15, semiconductor apparatus 105 is different from semiconductor apparatus 101 in that the plurality of first trench gates 11 each have a plurality of electrode portions 13a and 13b in first trench 17. For semiconductor apparatus 105, at least one first trench gate 11 may have the plurality of electrode portions 13a and 13b. The at least one first trench gate 11 may have three or more electrode portions.

The plurality of electrode portions 13a and 13b are spaced from each other in first trench 17 in third direction DR3 intersecting first surface 10A. Insulating film 14 is provided so as to cover the plurality of electrode portions 13a and 13b in first trench 17. First trench gate 11 has electrode portion 13a and electrode portion 13b separated by a portion of insulating film 14 that is located between charge accumulation regions 4 in second direction DR2, for example.

Semiconductor apparatus 105 can reduce more noise than semiconductor apparatus 101 can. Note that first trench gate 11 may be formed in any method. For example, an insulating film is deposited in first trench 17, electrode portion 13a is subsequently formed, an insulating film is subsequently deposited on electrode portion 13a, and electrode portion 13b is further formed on that insulating film. First trench gate 11 can also be formed in this way.

Semiconductor apparatus 105 may have a configuration similar to that of any of the semiconductor apparatuses of the second to fourth embodiments except that the plurality of first trench gates 11 each have a plurality of electrode portions 13a and 13b in first trench 17.

### Sixth Embodiment

A semiconductor apparatus according to a sixth embodiment is identical in configuration as well as function and effect to the first embodiment unless otherwise specified. Accordingly, any configuration identical to that of the first embodiment will identically be denoted and will not be described repeatedly.

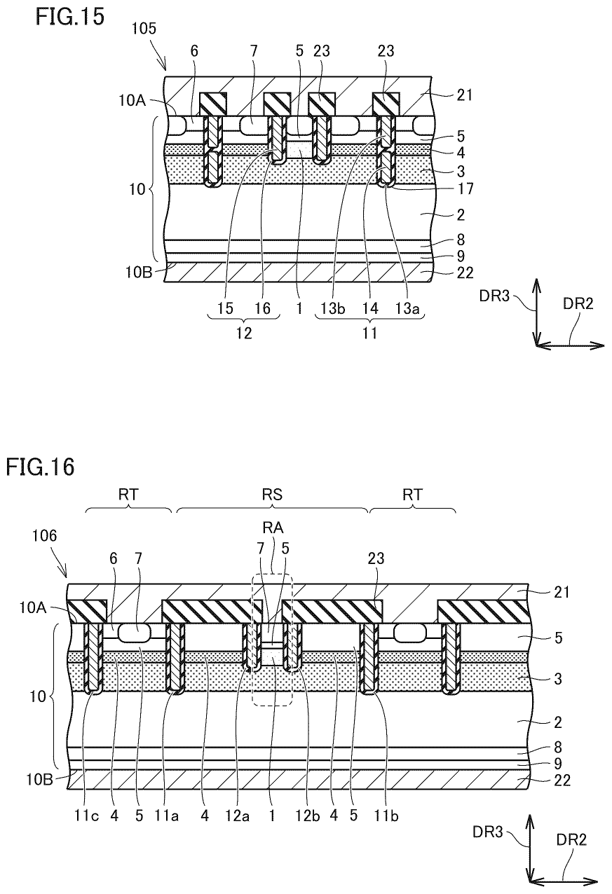

FIG. 16 is a cross section of an example of a semiconductor apparatus 106 according to the sixth embodiment. As shown in FIG. 16, semiconductor apparatus 106 is different from semiconductor apparatus 101 in that, between first first trench gate 11a and the second first trench gate, contact region 7 is only disposed between the plurality of second trench gates 12.

The plurality of first trench gates 11 include first first trench gate 11a and second first trench gate 11b and, in addition, further include a third first trench gate 11c provided on a side opposite to second first trench gate 11b with first first trench gate 11a interposed therebetween. A spacing between first first trench gate 11a and second first trench gate 11b is larger than a spacing between first first trench gate 11a and third first trench gate 11c.

The plurality of second trench gates 12 are only disposed between first first trench gate 11a and second first trench gate 11b. The plurality of second trench gates 12 are not disposed between first first trench gate 11a and third first trench gate 11c.

Semiconductor apparatus 106 comprises a region RT in which a bipolar transistor is formed and a region RS in which charge is accumulated.

Region RT is located between first first trench gate 11a and third first trench gate 11c. Region RT includes source region 6 and contact region 7. Region RT has source region 6 and contact region 7 electrically connected to first electrode 21.

Region RS is located between first first trench gate 11a and second first trench gate 11b. Region RS does not include source region 6. Region RS includes contact region 7 only between first first trench gate 11a and second first trench gate 11b. Region RS has contact region 7 electrically connected to first electrode 21.

Semiconductor apparatus 106 can also efficiently discharge electrical charge (e.g., holes) accumulated in region RS. Furthermore, semiconductor apparatus 106 allows input capacitance and feedback capacitance to be reduced as a region which is not electrically connected to first electrode 21 (a region free of emitter contact) is formed in region RS between first first trench gate 11a and first second trench gate 12a.

### <Variation of Semiconductor Apparatus 106>

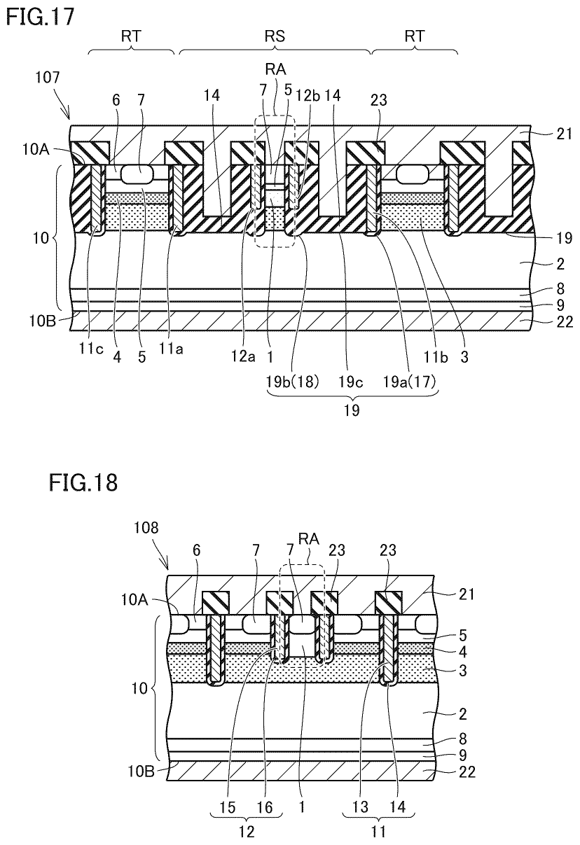

FIG. 17 is a cross section of a semiconductor apparatus 107, which is a variation of semiconductor apparatus 106. As shown in FIG. 17, semiconductor apparatus 107 is identical to semiconductor apparatus 106 in that between first first trench gate 11a and the second first trench gate, contact region 7 is only disposed between the plurality of second trench gates 12. Therefore, semiconductor apparatus 107 is similar in function and effect to semiconductor apparatus 106. In contrast, semiconductor apparatus 107 is different from semiconductor apparatus 106 in that a third trench 19 is formed in semiconductor substrate 10.

Third trench 19 has an internal wall surface with insulating film 14 formed thereon. First electrode 21 is buried in third trench 19 at a space inner than insulating film 14.

Third trench 19 has a first portion 19a corresponding to first trench 17, a second portion 19b corresponding to second trench 18, and a third portion 19c bridged between the first portion and the second portion. A height of a region located in semiconductor substrate 10 between two adjacent first trenches 17 from the bottom surface of first portion 19a is higher than a height of the region from the bottom surface of third portion 19c.

Third trench 19 may have first portion 19a, second portion 19b, and third portion 19c in any relationship in magnitude in depth from first surface 10A. Second portion 19b is as deep as first portion 19a from first surface 10A for example. Second portion 19b may be larger or smaller in depth from first surface 10A than first portion 19a is, for example. Third portion 19c is smaller in depth from first surface 10A than each of first portion 19a and second portion 19b is, for example.

Semiconductor apparatuses 106 and 107 may be similar in configuration to any of the semiconductor apparatuses of the second to fifth embodiments except that between first first trench gate 11a and the second first trench gate, contact region 7 is only disposed between the plurality of second trench gates 12.

### Seventh Embodiment

A semiconductor apparatus according to a seventh embodiment is identical in configuration as well as function and effect to the first embodiment unless otherwise specified. Accordingly, any configuration identical to that of the first embodiment will identically be denoted and will not be described repeatedly.

FIG. 18 is a cross section of an example of a semiconductor apparatus 108 according to the seventh embodiment. As shown in FIG. 18, semiconductor apparatus 108 is different from semiconductor apparatus 101 in that first region 1 is provided in contact with contact region 7. Semiconductor apparatus 108 has first region 1 formed through diffusion of the second conduction type impurity for forming channel doped layer 5 in a region other than region RA. Semiconductor apparatus 108 has first region 1 with an impurity density gradually increasing toward first surface 10A. Semiconductor apparatus 108 may have first region 1 of the first conduction type or the second conduction type.

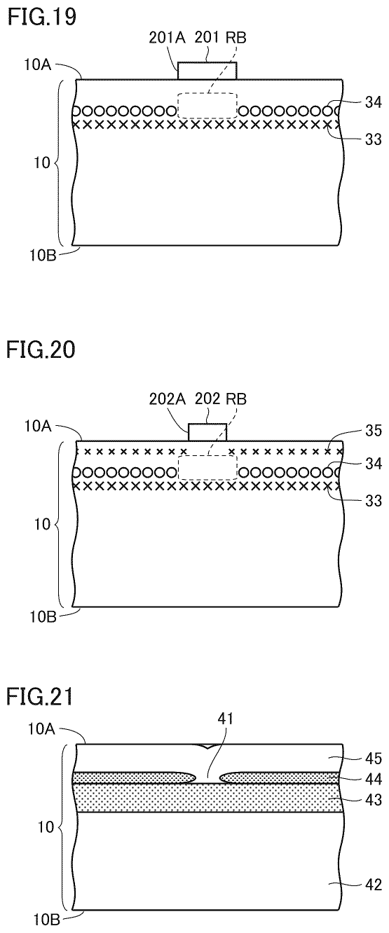

FIGS. 19 to 21 are cross sections for illustrating an example of a method for manufacturing semiconductor apparatus 108 having first region 1 of the second conduction type. More specifically, FIGS. 19 to 21 show sub-steps of the step (S20) of implanting impurities through first surface 10A of the semiconductor substrate for forming body layer 3, charge accumulation region 4, channel doped layer 5, and first region 1. The method for manufacturing semiconductor apparatus 108 is different from the method for manufacturing semiconductor apparatus 101 in that in the step (S20) after the step shown in FIG. 5 the steps shown in FIGS. 6 to 8 are not performed and the steps shown in FIGS. 19 to 21 are instead performed.

As shown in FIG. 19, in the method for manufacturing semiconductor apparatus 108, first conduction type impurity 34 for forming charge accumulation region 4 is alone implanted into semiconductor substrate 10 via mask 201 (a first mask) to form a first implantation region in semiconductor substrate 10. Subsequently, mask 201 is removed from first surface 10A.

Subsequently, as shown in FIG. 20, a mask 202 (a second mask) having an opening 202A is formed on first surface 10A. Opening 202A (a second opening) of mask 202 is larger than opening 201A (a first opening) of mask 201. Opening 202A opens on a portion of a region in which first region 1 is to be formed, and also opens throughout a region in which channel doped layer 5 is to be formed. Subsequently, second conduction type impurity 35 for forming first region 1 and channel doped layer 5 is implanted into semiconductor substrate 10 through mask 202 to form a second implantation region in semiconductor substrate 10. A portion of second conduction type impurity 35 is implanted on and in region RB.

Subsequently, after the step (S20), semiconductor substrate 10 is heated to diffuse into semiconductor substrate 10 the impurities implanted in the step (S20) (S30). This diffuses into region RB at least a portion of second conduction type impurity 35 implanted on region RB in the step (S20). As a result, as shown in FIG. 21, impurity regions 41, 43, 44, and 45 corresponding to first region 1, body layer 3, charge accumulation region 4, and channel doped layer 5, respectively, are formed in semiconductor substrate 10. First region 1 and channel doped layer 5 are formed from the second implantation region in which second conduction type impurity 35 is implanted.

The method for manufacturing semiconductor apparatus 108 allows first region 1 to be formed in the step (S20) with channel doped layer 5 simultaneously, and thus allows the second conduction type impurity to be implanted through a reduced number of steps. As a result, semiconductor apparatus 108 can be manufactured at a smaller cost than semiconductor apparatus 101.

### <Variation of Method for Manufacturing Semiconductor Apparatus 108>

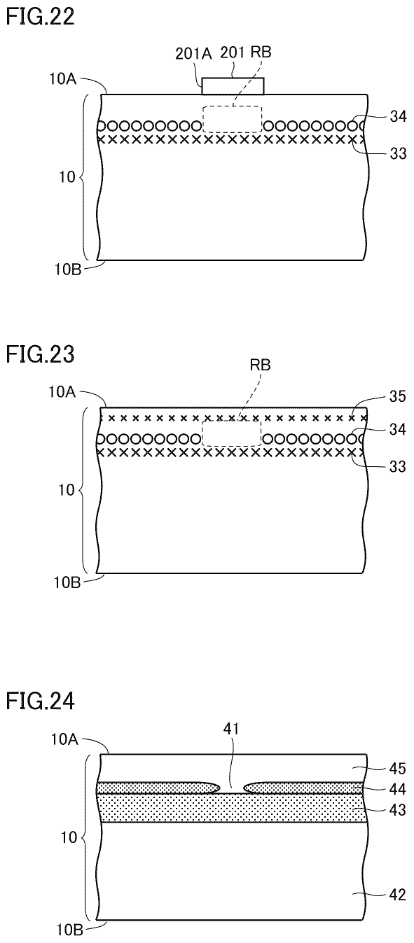

FIGS. 22 to 24 are cross sections showing a first variation of the method for manufacturing semiconductor apparatus 108 having first region 1 of the second conduction type. FIGS. 22 to 24 show a first variation of sub-steps of the step (S20). In the first variation of the method for manufacturing semiconductor apparatus 108, the step (S20) is performed such that after the step shown in FIG. 5 the steps shown in FIGS. 19 to 21 are not performed and the steps shown in FIGS. 22 to 24 are instead performed.

As shown in FIG. 22, in the first variation, first conduction type impurity 34 for forming charge accumulation region 4 is alone implanted into semiconductor substrate 10 via mask 201 (the first mask) to form the first implantation region in semiconductor substrate 10. Subsequently, mask 201 is removed from first surface 10A.

Subsequently, as shown in FIG. 23, second conduction type impurity 35 for forming first region 1 and channel doped layer 5 is implanted into semiconductor substrate 10 without using a mask to form the second implantation region in semiconductor substrate 10. A portion of second conduction type impurity 35 is implanted on and in region RB.

Subsequently, after the step (S20), semiconductor substrate 10 is heated to diffuse into semiconductor substrate 10 the impurities implanted in the step (S20) (S30). This diffuses into region RB at least a portion of second conduction type impurity 35 implanted on region RB in the step (S20). As a result, as shown in FIG. 24, impurity regions 41, 43, 44, and 45 corresponding to first region 1, body layer 3, charge accumulation region 4, and channel doped layer 5, respectively, are formed in semiconductor substrate 10. First region 1 and channel doped layer 5 are formed from the second implantation region in which second conduction type impurity 35 is implanted.

The first variation also allows first region 1 to be formed in the step (S20) with channel doped layer 5 simultaneously, and thus allows the second conduction type impurity to be implanted through a reduced number of steps. Furthermore, the first variation allows first region 1 to be formed with channel doped layer 5 simultaneously without using the second mask used in the step shown in FIG. 20. Therefore, semiconductor apparatus 108 manufactured in the first variation can be manufactured at a further smaller cost than semiconductor apparatus 108 manufactured in the method shown in FIGS. 19 to 21.

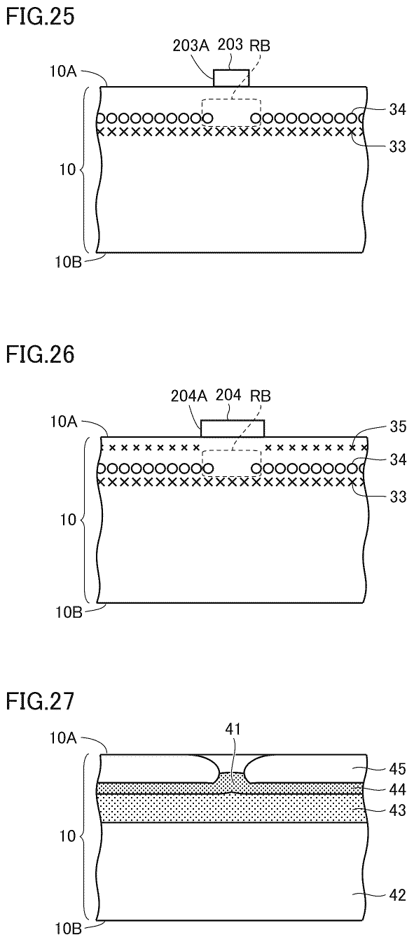

FIGS. 25 to 27 are cross sections for illustrating a method for manufacturing semiconductor apparatus 108 having first region 1 of the first conduction type as a second variation of the method for manufacturing semiconductor apparatus 108. FIGS. 25 to 27 illustrate sub-steps of the step (S20). In the second variation, the step (S20) is performed such that after the step shown in FIG. 5 the steps shown in FIGS. 19 to 21 are not performed and the steps shown in FIG. 25 to FIG. 27 are instead performed.

As shown in FIG. 25, in the second variation, a mask 203 (a third mask) having an opening 203A is formed on first surface 10A. Opening 203A (a third opening) of mask 203 opens on a portion of the region in which first region 1 is to be formed, and also opens throughout the region in which charge accumulation region 4 is to be formed. Subsequently, first conduction type impurity 34 for forming first region 1 and charge accumulation region 4 is implanted into semiconductor substrate 10 through mask 203 to form a fourth implantation region in semiconductor substrate 10. A portion of first conduction type impurity 34 is implanted in region RB. Subsequently, mask 203 is removed from first surface 10A.

Subsequently, as shown in FIG. 26, a mask 204 (a fourth mask) having an opening 204A is formed on first surface 10A. Opening 204A (a fourth opening) of mask 204 is smaller than opening 203A of mask 203. Opening 204A opens on a portion of the region in which channel doped layer 5 is to be formed. Mask 204 covers entirely the region in which first region 1 is to be formed. Subsequently, second conduction type impurity 35 for forming channel doped layer 5 is implanted into semiconductor substrate 10 through mask 204 to form a fifth implantation region in semiconductor substrate 10. A portion of second conduction type impurity 35 is neither implanted on nor in region RB. Subsequently, mask 204 is removed from first surface 10A.

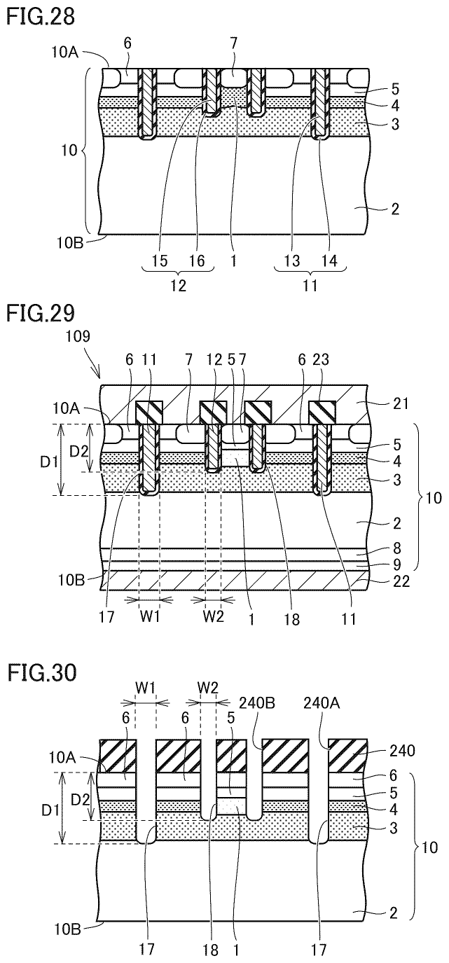

Subsequently, after the step (S20), semiconductor substrate 10 is heated to diffuse into semiconductor substrate 10 the impurities implanted in the step (S20) (S30). This diffuses into region RB at least a portion of first conduction type impurity 34 implanted in and around region RB in the step (S20). A portion of first conduction type impurity 34 diffuses toward first surface 10A. As a result, as shown in FIG. 27, impurity regions 41, 43, 44, and 45 corresponding to first region 1, body layer 3, charge accumulation region 4, and channel doped layer 5, respectively, are formed in semiconductor substrate 10. Thereafter, the steps (S40) to (S80) shown in FIG. 4 are performed to form first region 1 and charge accumulation region 4 from impurity region 41 and impurity region 44, respectively, as shown in FIG. 28.

The method for manufacturing semiconductor apparatus 108 allows first region 1 to be formed in the step (S20) with charge accumulation region 4 simultaneously, and thus allows the first conduction type impurity to be implanted through a reduced number of steps. As a result, semiconductor apparatus 108 can be manufactured at a smaller cost than semiconductor apparatus 101.

Semiconductor apparatus 108 may be similar in configuration to the semiconductor apparatus of any of the second to sixth embodiments except that first region 1 is provided in contact with contact region 7. The method for manufacturing the semiconductor apparatus of any of the second to sixth embodiments with first region 1 of the second conduction type may comprise the steps shown in FIGS. 19 to 21, the steps shown in FIGS. 22 to 24, or the steps shown in FIGS. 25 to 27.

### Eighth Embodiment

A semiconductor apparatus according to an eighth embodiment is identical in configuration as well as function and effect to the first embodiment unless otherwise specified. Accordingly, any configuration identical to that of the first embodiment will identically be denoted and will not be described repeatedly.

FIG. 29 is a cross section of an example of a semiconductor apparatus 109 according to the eighth embodiment. As shown in FIG. 29, semiconductor apparatus 109 is different from semiconductor apparatus 101 in that the plurality of second trenches 18 each have an opening with a width W2 and first trench 17 has an opening with a width W1, the width W2 being smaller than the width W1.

Semiconductor apparatus 109 has first trench 17 and second trench 18 formed simultaneously.

FIG. 30 is a cross section for illustrating an example of a method for manufacturing semiconductor apparatus 109. More specifically, FIG. 30 shows a sub-step in forming first trench gate 11 and second trench gate 12 in semiconductor substrate 10 (S60).

As shown in FIG. 30, in the step (S60), a trench mask 240 having an opening 240A (a fifth opening) and a plurality of openings 240B (a sixth opening) is formed on first surface 10A. Opening 240A opens on a region in which first trench 17 is to be formed. Opening 240B opens on a region in which second trench 18 is to be formed. Opening 240B is smaller in width than opening 240A in second direction DR2.

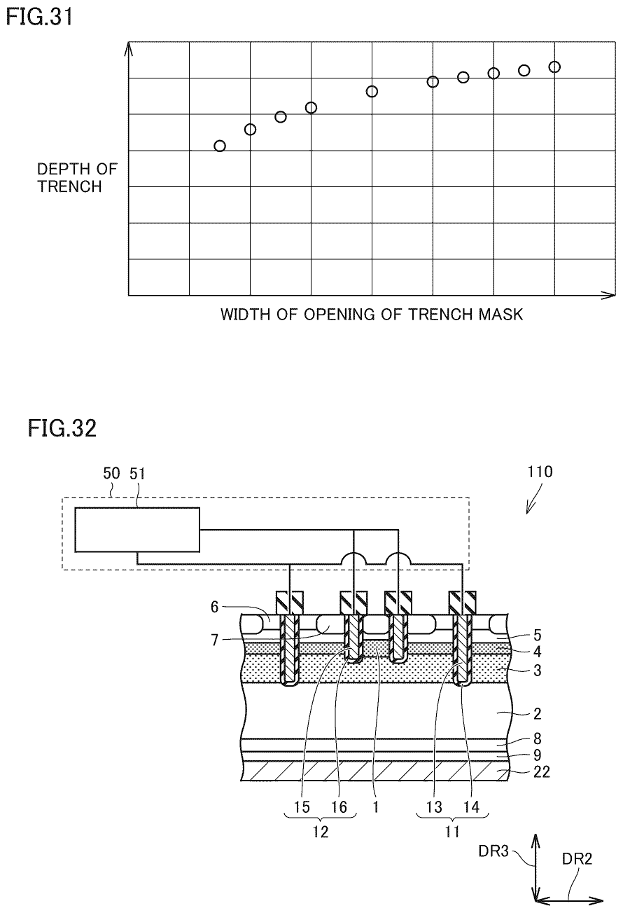

This step exploits a nature of a trench to have a depth depending on a width of an opening of a trench mask under a given etching condition. FIG. 31 is a graph for illustrating a nature of a trench to have a depth depending on a width of an opening of a trench mask under a given etching condition. As represented in FIG. 31, as the trench mask has an opening increasing in width in second direction DR2, etching semiconductor substrate 10 through the opening of the trench mask forms a deeper trench. In the method for manufacturing semiconductor apparatus 109, a nature of a trench to have a depth depending on a width of an opening of a trench mask is previously evaluated for semiconductor substrate 10, and a width of an opening of a trench mask is set based on a result of the evaluation to correspond to a depth of a trench to be formed. Then, trench mask 240 having an opening with a preset width is formed on first surface 10A and used to perform this step. Thus, as shown in FIG. 30, first trench 17 and second trench 18 different in depth from first surface 10A can be simultaneously formed using a single trench mask 240.

The method for manufacturing semiconductor apparatus 109 allows the step (S60) to be performed with a reduced number of sub-steps. As a result, semiconductor apparatus 109 can be manufactured at a smaller cost than semiconductor apparatus 101.

### Ninth Embodiment

A semiconductor apparatus according to a ninth embodiment is identical in configuration as well as function and effect to the first embodiment unless otherwise specified. Accordingly, any configuration identical to that of the first embodiment will identically be denoted and will not be described repeatedly.

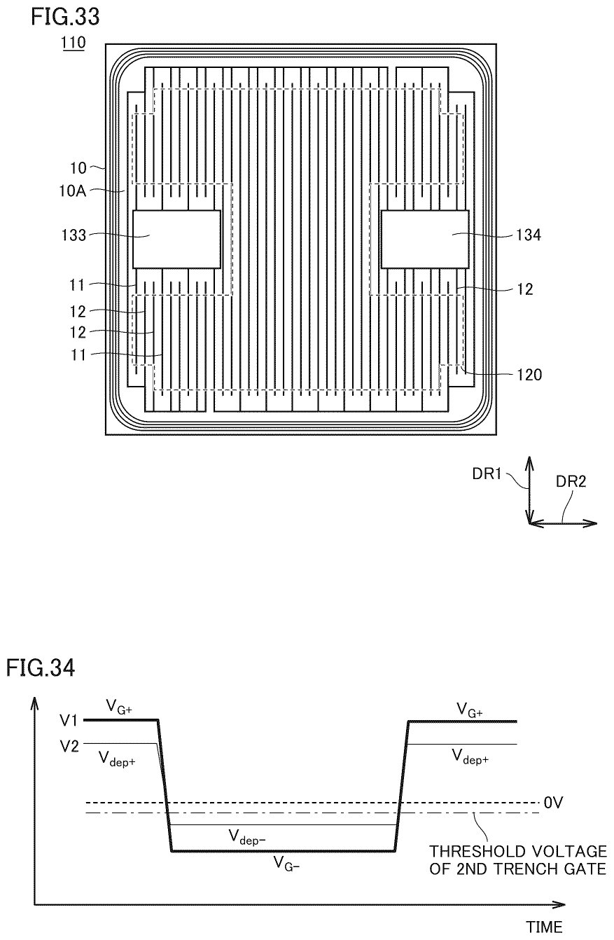

FIGS. 32 and 33 schematically show an example of a semiconductor apparatus 110 according to the ninth embodiment. As shown in FIGS. 32 and 33, semiconductor apparatus 110 is different from semiconductor apparatus 101 in allowing different voltages to be applied to at least one first trench gate 11 and the plurality of second trench gates 12. As shown in FIG. 33, semiconductor apparatus 110 is different from semiconductor apparatus 101 in comprising a first gate pad 133 electrically connected to each of the plurality of first trench gates 11 and a second gate pad 134 electrically connected to each of the plurality of second trench gates 12. First gate pad 133 and second gate pad 134 are for example spaced from each other in second direction DR2. The plurality of first trench gates 11 each have a portion extending from first gate pad 133 in first direction DR1 and a comb-shaped portion that is contiguous to the portion extending from the first gate pad in the first direction and has teeth spaced from one another in second direction DR2. Similarly, the plurality of second trench gates 12 each have a portion extending from second gate pad 134 in first direction DR1 and a comb-shaped portion that is contiguous to the portion extending from the second gate pad in the first direction and has teeth spaced from one another in second direction DR2. The comb-shaped portion of first trench gate 11 and the comb-shaped portion of second trench gate 12 are opposed to each other in first direction DR1 or second direction DR2.

As shown in FIG. 32, semiconductor apparatus 110 further comprises a drive circuit 50 to control a switching operation of the bipolar transistor. Drive circuit 50 can apply different voltages to the at least one first trench gate 11 and the plurality of second trench gates 12. Drive circuit 50 includes a controller 51 and wiring that electrically interconnects controller 51 to each of first trench gate 11 and second trench gate 12.

FIG. 34 is a waveform diagram for illustrating a relationship in magnitude between a voltage V1 applied to first trench gate 11 and a voltage V2 applied to second trench gate 12 and a timing of applying each voltage when semiconductor apparatus 110 is turned off, steadily off, turned on and steadily on. In FIG. 34, a thick solid line indicates a waveform of the voltage V1 applied to first trench gate 11, and a thin solid line indicates a waveform of the voltage V2 applied to second trench gate 12.

As shown in FIG. 34, when semiconductor apparatus 110 has the bipolar transistor in a steady off state, an off voltage V_{G-} is applied to at least one first trench gate 11, and a first voltage V_{dep-} smaller than a threshold voltage set for second trench gate 12 is applied to each of the plurality of second trench gates 12. The threshold voltage of second trench gate 12 is defined as a maximum potential difference between second trench gate 12 and first region 1 necessary to maintain in region RA a channel that can serve as a hole discharging path.

When semiconductor apparatus 110 has the bipolar transistor in a steady on state, an on voltage V_{G+} is applied to at least one first trench gate 11, and a second voltage V_{dep+} larger than the threshold voltage is applied to each of the plurality of second trench gates 12.

When first region 1 is of the second conduction type (e.g., the p-type), the threshold voltage of second trench gate 12 corresponds to a flat band voltage. The flat band voltage depends on a work function difference between a material forming the electrode portion of second trench gate 12 and a semiconductor material forming semiconductor substrate 10. As an example, when second trench gate 12 has the electrode portion formed of doped polysilicon and semiconductor substrate 10 is formed of a semiconductor material of Si, the threshold voltage will be about −0.8 V as source region 6 (the emitter region) is of a p+ type. In that case, when a voltage larger than the threshold voltage is applied to second trench gate 12, a depletion layer spreads in region RA and a channel that can serve as a hole discharging path is not formed in region RA, which suppresses discharging holes from region RA. In contrast, when a voltage equal to or lower than the threshold voltage is applied to second trench gate 12, the hole discharging path is formed in region RA and thus facilitates discharging holes. As shown in FIG. 34, a voltage applied to second trench gate 12 at the time of turning off becomes equal to or lower than the threshold voltage, and this state is held during the steady off state. As a result, discharging holes from region RA is facilitated at the time of turning off and in the steady off state.

When first region 1 is of the first conduction type (e.g., the n type), and for example first region 1 has an n-type impurity density of 1e¹⁴/cm², the threshold voltage for second trench gate 12 will be about −1.3 V. When a voltage larger than the threshold voltage is applied to second trench gate 12, a depletion layer formed in the pnp structure in region RA suppresses discharging holes from region RA. In contrast, when a voltage equal to or lower than the threshold voltage is applied to second trench gate 12, a p-type channel along second trench 18 is formed in first region 1. As a result, discharge holes from region RA is facilitated at the time of turning off and in the steady off state.

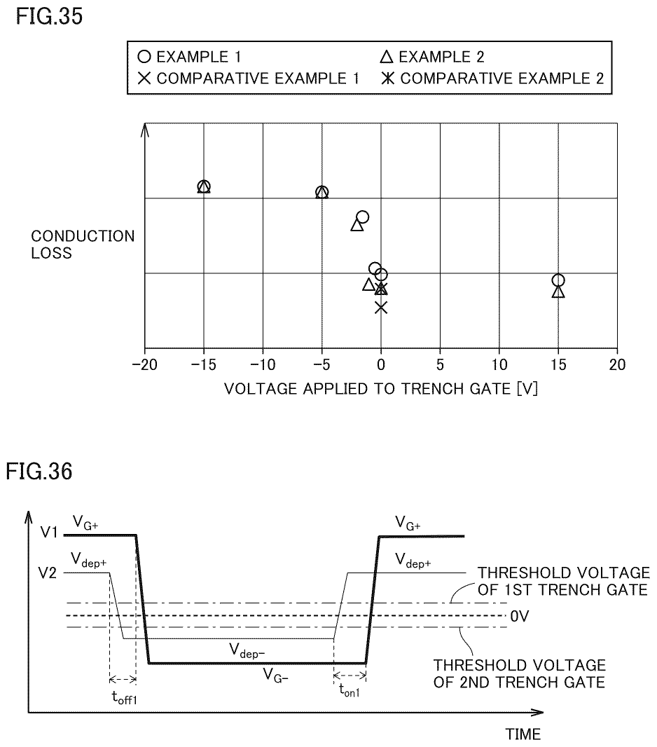

FIG. 35 is a graph representing a result of a simulation of a relationship between voltage applied to a trench gate in a steady on state and conduction loss. FIG. 35 shows the above evaluation result for an Example 1 having first region 1 of a p conduction type and an Example 2 having first region 1 of an n conduction type, and a Comparative Example 1 that is the Carrier Stored Trench-Gate Bipolar Transistor® (CSTBT) which does not comprise the first region and a Comparative Example 2 that is an IGBT which does not comprise the first region and has the Super Body Layer (SBL) structure. The evaluation results of Examples 1 and 2 show a relationship between a voltage applied to second trench gate 12 in the steady on state and conduction loss. As shown in FIG. 35, Examples 1 and 2 in an on state in which a positive voltage is applied to second trench gate 12 provide a conduction loss of the same extent as a conduction loss that Comparative Examples 1 and 2 provide. As shown in FIG. 35, Examples 1 and 2 in an off state in which a voltage equal to or smaller than the threshold voltage of second trench gate 12 is applied thereto provide a conduction loss larger than Comparative Examples 1 and 2 do, as the former facilitates discharging holes from region RA.

Semiconductor apparatus 110 allows a voltage applied to each of the second trench gates 12 to be set as desired without being limited by a voltage applied to first trench gate 11. As a result, when semiconductor apparatus 110 is compared with semiconductor apparatus 101, the former further easily co-establishes suppression of conduction loss in the on state and suppression of switching loss at the time of turning off.

### Tenth Embodiment

A semiconductor apparatus according to a tenth embodiment is identical in configuration as well as function and effect to the ninth embodiment unless otherwise specified. Accordingly, any configuration identical to that of the first embodiment will identically be denoted and will not be described repeatedly.

In the semiconductor apparatus according to the tenth embodiment, drive circuit 50 can apply different voltages to at least one first trench gate 11 and the plurality of second trench gates 12 with different timings when the bipolar transistor performs a switching operation.

FIG. 36 is a waveform diagram for illustrating a relationship in magnitude between a voltage applied to first trench gate 11 and a voltage applied to second trench gate 12 and a timing of applying each voltage when the semiconductor apparatus according to the tenth embodiment is turned off, steadily off, turned on and steadily on. In FIG. 36, a thick solid line indicates a waveform of the voltage V1 applied to first trench gate 11, and a thin solid line indicates a waveform of the voltage V2 applied to second trench gate 12.

As shown in FIG. 36, preferably, at the time of turning off, the first voltage V_{dep-} is applied to each of the plurality of second trench gates 12, and thereafter the off voltage V_{G-} is applied to at least one first trench gate 11. More preferably, at the time of turning on, the second voltage V_{dep+} is applied to each of the plurality of second trench gates 12, and thereafter the on voltage V_{G+} is applied to at least one first trench gate 11.

Drive circuit 50 includes a second turn-off circuit and a second turn-on circuit electrically connected to each of the plurality of second trench gates 12. In turning off the bipolar transistor, let t_{off1} represent a first time difference elapsing after a voltage applied to the plurality of second trench gates 12 changes from the second voltage V_{dep+} before a voltage applied to at least one first trench gate 11 changes from the on voltage. In turning on the bipolar transistor, let tₒₙ₁ represent a second time difference elapsing after a voltage applied to the plurality of second trench gates 12 changes from the first voltage V_{dep-} before a voltage applied to at least one first trench gate 11 changes from the off voltage. Cᵢₑₛ₂ represents an input capacitance of the plurality of second trench gates 12 (unit: pF), V_{dep-} represents the first voltage (unit: V), V_{dep+} represents the second voltage (unit: V), R_{Goff2} represents a gate resistance of the second turn-off circuit (unit: Ω), R_{Gon2} represents a gate resistance of the second turn-on circuit (unit: Ω), and α represents an arbitrary coefficient larger than 0 and smaller than 1 (0<α<1). The arbitrary coefficient α is an index for calculating a time difference as it is determined that a value set for a voltage applied to first trench gate 11 or second trench gate 12 is reached when a value of 100*α% of the set value is reached. The arbitrary coefficient α may be 0.95.

More preferably, the first time difference t_{off1} and the second time difference tₒₙ₁ satisfy the following relational expressions (2) and (3):

$${t}_{off 1} > {C}_{i e s 2} {R}_{Goff 2} ln [ \frac{{V}_{dep +} - {V}_{dep -}}{{V}_{dep -} ( 1 - α )} ] and \qquad ( 2 )$$

$${t}_{on 1} > {C}_{i e s 2} {R}_{Gon 2} ln [ \frac{{V}_{dep +} - {V}_{dep -}}{{V}_{dep +} ( 1 - α )} ] , \qquad ( 3 )$$

respectively.

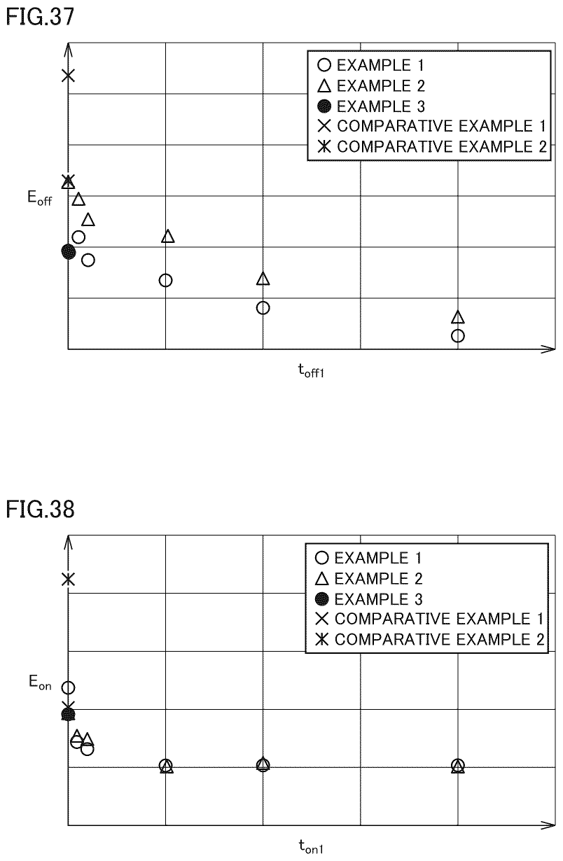

FIG. 37 is a graph showing a result of a simulation for a relationship between the first time difference t_{off1} and a switching loss E_{off} caused at the time of turning off. FIG. 38 is a graph showing a result of a simulation of a relationship between the second time difference tₒₙ₁ and a switching loss Eₒₙ caused at the time of turning on. FIGS. 37 and 38 show the above evaluation result for Examples 1, 2 and 3 and Comparative Examples 1 and 2. Example 1 has first region 1 of a p conduction type. Example 2 has first region 1 of an n conduction type. Examples 1 and 2 are evaluated for the switching loss E_{off} and the switching loss Eₒₙ while the first time difference t_{off1} and the second time difference tₒₙ₁ are different between Examples 1 and 2. Example 3 has first region 1 of the p conduction type and first trench gate 11 and second trench gate 12 each connected to a common gate pad and applies equal voltage to each trench gate with the same timing to perform turning on and off. Comparative Examples 1 and 2 also have each trench gate connected to a common gate pad and apply equal voltage to each trench gate with the same timing to perform turning on and off. Therefore, for Example 3 and Comparative Examples 1 and 2, the first time difference t_{off1} and the second time difference tₒₙ₁ are zero.

As shown in FIGS. 37 and 38, it has been confirmed that Example 3 can achieve smaller switching losses E_{off} and Eₒₙ than Comparative Examples 1 and 2. It has been confirmed that Examples 1 and 2 with turning-off and turning-on operations performed in the manner shown in FIG. 36 can achieve smaller switching losses E_{off} and Eₒₙ than Example 3 and Comparative Examples 1 and 2.

The semiconductor apparatus according to the tenth embodiment at each of the time of turning on and the time of turning off allows voltage to be applied to second trench gate 12 to cause first region 1 to act for accumulating and discharging holes, as described above, and thereafter allows voltage to be applied to first trench gate 11. As a result, the semiconductor apparatus according to the tenth embodiment can achieve a smaller switching loss than semiconductor apparatus 101 according to the first embodiment.

### Eleventh Embodiment

A semiconductor apparatus according to an eleventh embodiment is identical in configuration as well as function and effect to the ninth embodiment unless otherwise specified. Accordingly, any configuration identical to that of the first embodiment will identically be denoted and will not be described repeatedly.

In the semiconductor apparatus according to the eleventh embodiment, drive circuit 50 can apply different voltages to at least one first trench gate 11 and the plurality of second trench gates 12 with different timings when the bipolar transistor performs a switching operation.

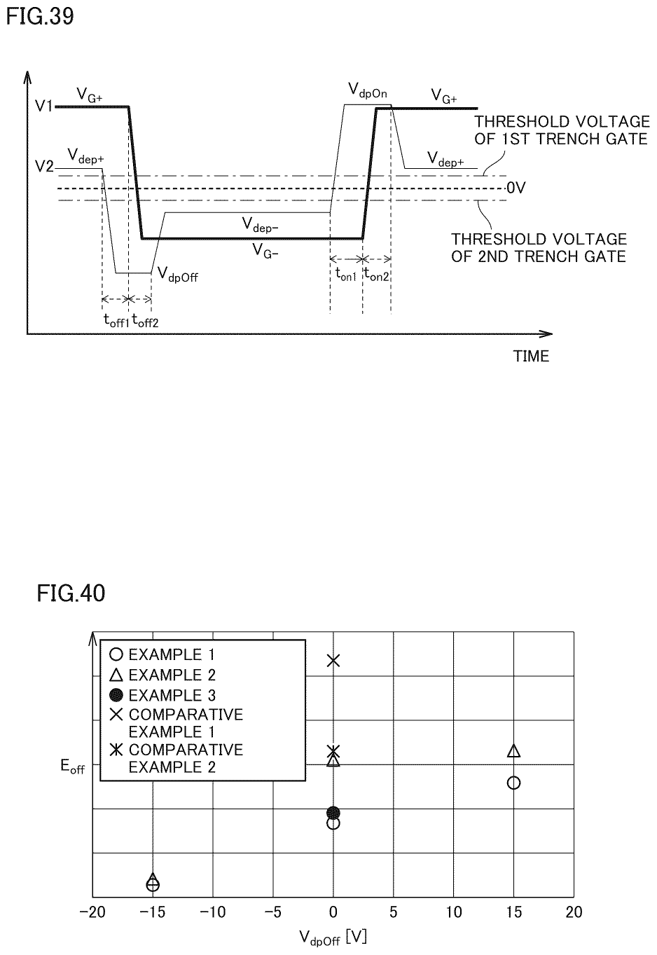

FIG. 39 is a waveform diagram for illustrating a relationship in magnitude between a voltage applied to first trench gate 11 and a voltage applied to second trench gate 12 and a timing of applying each voltage when the semiconductor apparatus according to the eleventh embodiment is turned off, steadily off, turned on and steadily on. In FIG. 39, a thick solid line indicates a waveform of the voltage V1 applied to first trench gate 11, and a thin solid line indicates a waveform of the voltage V2 applied to second trench gate 12.

As shown in FIG. 39, in the semiconductor apparatus according to the eleventh embodiment, in turning off the bipolar transistor, a third voltage V_{dpoff} smaller than the first voltage V_{dep-} is applied to each of the plurality of second trench gates 12, and thereafter the first voltage V_{dep-} is applied thereto. In turning off the bipolar transistor as above, the off voltage is applied to at least one first trench gate 11 after the third voltage is applied to each of the plurality of second trench gates 12 before the first voltage V_{dep-} is applied thereto.

In the semiconductor apparatus according to the eleventh embodiment, in turning on the bipolar transistor, a fourth voltage V_{dpon} larger than the second voltage V_{dep+} is applied to each of the plurality of second trench gates 12, and thereafter the second voltage V_{dep+} is applied thereto. In turning on the bipolar transistor as above, the on voltage is applied to at least one first trench gate 11 after the fourth voltage is applied to each of the plurality of second trench gates 12 before the second voltage V_{dep+} is applied thereto.

Drive circuit 50 includes the second turn-off circuit and the second turn-on circuit electrically connected to each of the plurality of second trench gates 12.

In turning off the bipolar transistor, let t_{off1} represent a first time difference elapsing after a voltage applied to the plurality of second trench gates 12 changes from the second voltage before a voltage applied to at least one first trench gate 11 changes from the on voltage. Let t_{off2} represent a third time difference elapsing after the voltage applied to at least one first trench gate 11 changes from the on voltage before a voltage applied to the plurality of second trench gates 12 changes from the third voltage.

In turning on the bipolar transistor, let tₒₙ₁ represent a second time difference elapsing after a voltage applied to the plurality of second trench gates 12 changes from the first voltage before a voltage applied to at least one first trench gate 11 changes from the off voltage. Let tₒₙ₂ represent a fourth time difference elapsing after the voltage applied to at least one first trench gate 11 changes from the off voltage before a voltage applied to the plurality of second trench gates 12 changes from the fourth voltage.

Cᵢₑₛ₂ represents an input capacitance of the plurality of second trench gates, V_{dep-} represents the first voltage, V_{dep+} represents the second voltage, R_{Goff2} represents a gate resistance of the second turn-off circuit, R_{Gon2} represents a gate resistance of the second turn-on circuit, and α represents an arbitrary coefficient larger than 0 and smaller than 1 (0<α<1). C_{iesACT} represents an input capacitance of at least one first trench gate 11 (unit: F). C_{resACT} represents a feedback capacitance of at least one first trench gate 11 (unit: F). R_{GoffACT} represents a gate resistance of the first turn-off circuit (unit: Ω). R_{GonACT} represents a gate resistance of the first turn-on circuit (unit: Ω). V_{G-} represents the off voltage and V_{G+} represents the on voltage. V_{Cpeak} represents a peak voltage applied to the bipolar transistor between the collector and the emitter (unit: V). V_{CEsat} represents a saturation voltage applied to the bipolar transistor between the collector and the emitter (unit: V). V_{Gplateau} represents a mirror voltage of the bipolar transistor (unit: V). tₚ represents a width of a pulse of a voltage applied to at least one first trench gate 11 (unit: s).

Preferably, the first time difference t_{off1} and the second time difference tₒₙ₁ satisfy the above relational expressions (2) and (3), respectively, the third time difference t_{off2} and the fourth time difference tₒₙ₂ satisfy the following relational expressions (4) and (5):

$${t}_{off 2} > {R}_{GoffAct} {C}_{iesAct} ln [ \frac{1}{{V}_{G -} ( 1 - α )} \{ ( {V}_{G +} - {V}_{G -} ) ( exp [ - \frac{{t}_{p}}{{R}_{GoffAct} {C}_{iesAct}} ] - 1 ) \} ] + {R}_{GoffAct} {C}_{iesAct} \frac{{V}_{Cpeak} - {V}_{CEsat}}{{V}_{Gplateau}} and \qquad ( 4 )$$

$${t}_{on 2} > {C}_{iesAct} {R}_{GonAct} ln [ \frac{{V}_{G +} - {V}_{G -}}{{V}_{G +} ( 1 - α )} ] + \frac{{R}_{GonAct} {C}_{resAct}}{{V}_{G +} - {V}_{Gplateau}} [ {V}_{CC} - {V}_{CEsat} ] , \qquad ( 5 )$$

respectively.

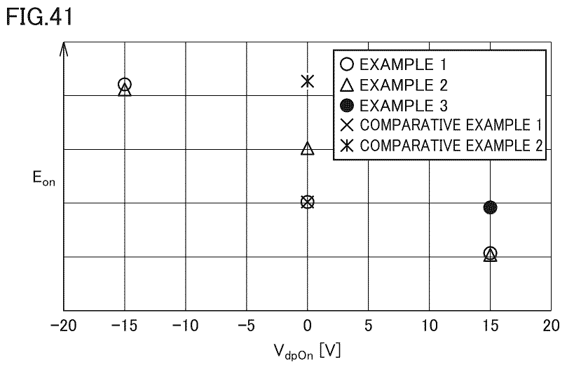

FIG. 40 is a graph showing a result of a simulation of a relationship between the third voltage V_{dpoff} applied to each of the plurality of second trench gates 12 at the time of turning off and the switching loss E_{off} at the time of turning off. FIG. 41 is a graph showing a result of a simulation of a relationship between the fourth voltage V_{dpon} applied to each of the plurality of second trench gates 12 at the time of turning on and the switching loss Eₒₙ at the time of turning on.

FIGS. 40 and 41 show the above evaluation result for Examples 1, 2 and 3 and Comparative Examples 1 and 2. Example 1 has first region 1 of a p conduction type. Example 2 has first region 1 of an n conduction type. Examples 1 and 2 are evaluated for the switching loss E_{off} and the switching loss Eₒₙ while the third voltage V_{dpoff} and the fourth voltage V_{dpon} are different between Examples 1 and 2. Example 3 has first region 1 of the p conduction type and first trench gate 11 and second trench gate 12 each connected to a common gate pad and applies equal voltage to each trench gate with the same timing to perform turning on and off. Comparative Examples 1 and 2 also have each trench gate connected to a common gate pad and apply equal voltage to each trench gate with the same timing to perform turning on and off.

As shown in FIGS. 40 and 41, it has been confirmed that Example 3 can achieve smaller switching losses E_{off} and Eₒₙ than Comparative Examples 1 and 2. It has been confirmed that Examples 1 and 2 with turning-off and turning-on operations performed in the manner shown in FIG. 39 can achieve smaller switching losses E_{off} and Eₒₙ than Example 3 and Comparative Examples 1 and 2. Furthermore, for Examples 1 and 2, it has been confirmed that the switching losses E_{off} and Eₒₙ both depend on the third voltage V_{dpoff} and fourth voltage V_{dpon} applied to second trench gate 12. It has been confirmed that, at the time of turning off, applying a voltage sufficiently smaller than the threshold voltage of second trench gate 12 to second trench gate 12 allows a significantly reduced switching loss. It has been confirmed that, at the time of turning on, applying a voltage sufficiently larger than the threshold voltage of second trench gate 12 to second trench gate 12 allows a significantly reduced switching loss.

Furthermore, for the semiconductor apparatus according to the eleventh embodiment, the first voltage V_{dep-} may be set as a minimum voltage necessary for discharging holes, as described above, in the steady off state. Similarly, the second voltage V_{dep+} may be set as a minimum voltage necessary for accumulating holes, as described above, in the steady on state. Thus, the semiconductor apparatus according to the eleventh embodiment can achieve smaller power consumption than semiconductor apparatus 101 according to the first embodiment.

### ADDITIONAL NOTES

Aspects of the present disclosure will be summarized as additional notes.

### Additional Note 1

A semiconductor apparatus comprising a bipolar transistor, comprising:
a semiconductor substrate having a first surface and a second surface opposite to the first surface;
at least one first trench gate and a plurality of second trench gates extending from the first surface of the semiconductor substrate toward the second surface of the semiconductor substrate; and
a first electrode provided on the first surface,
the semiconductor substrate including:
   a drift layer;
   a body layer located closer to the first surface than the drift layer is;
   a charge accumulation region located on the body layer; and
   a source region and a contact region formed in the first surface and electrically connected to the first electrode,
the plurality of second trench gates being each smaller in depth from the first surface than the at least one first trench gate is,
the at least one first trench gate penetrating the source region, the charge accumulation region, and the body layer to reach the drift layer,
the plurality of second trench gates being spaced from and adjacent to one another,
between adjacent ones of the plurality of second trench gates, the semiconductor substrate including the body layer, the contact region, and a first region located between the body layer and the contact region and having an impurity density lower than that of the body layer.

### Additional Note 2

The semiconductor apparatus according to Additional Note 1, wherein the first region has the impurity density in a profile having a local minimum in a direction intersecting the first surface.

### Additional Note 3

The semiconductor apparatus according to Additional Note 1 or 2, wherein the semiconductor substrate between adjacent ones of the plurality of second trench gates further includes a channel doped layer located between the contact region and the first region and having an impurity density higher than that of the body layer.

### Additional Note 4

The semiconducting apparatus according to any one of Additional Notes 1 to 3, wherein
the plurality of second trench gates are disposed in a plurality of second trenches formed in the semiconductor substrate at the first surface,
the first region is of a conduction type identical to that of the body layer, and
the plurality of second trenches have a spacing Wp therebetween satisfying the above-indicated relational expression (1), where Wp represents the spacing between the plurality of second trenches, N_{A} represents the impurity density of the first region, nᵢ represents an intrinsic carrier density of a semiconductor material forming the first region, ε represents a dielectric constant of the semiconductor material forming the first region, k_{B} represents a Boltzmann coefficient, T represents an absolute temperature, and q represents an elementary charge.

### Additional Note 5

The semiconductor apparatus according to Additional Note 4, wherein
the at least one first trench gate is a plurality of first trench gates spaced from one another, and
the plurality of second trench gates are three or more second trench gates disposed between the plurality of first trench gates and are formed in three or more second trenches formed in the semiconductor substrate.

### Additional Note 6

The semiconductor apparatus according to any one of Additional Notes 1 to 5, wherein the at least one first trench gate includes: a plurality of electrode portions that are disposed in at least one first trench formed in the semiconductor substrate at the first surface and are spaced from one another in a direction intersecting the first surface; and a gate insulating film that covers the plurality of electrode portions in the at least one first trench.

### Additional Note 7

The semiconductor apparatus according to any one of Additional Notes 1 to 6, wherein
the at least one first trench gate has a first first trench gate, a second first trench gate provided on one side with respect to the first first trench gate, and a third first trench gate provided on a side opposite to the second first trench gate with respect to the first first trench gate,
a spacing between the first first trench gate and the second first trench gate is larger than a spacing between the first first trench gate and the third first trench gate,
the plurality of second trench gates are only disposed between the first first trench gate and the second first trench gate, and
between the first first trench gate and the second first trench gate the contact region is only disposed between the plurality of second trench gates.

### Additional Note 8

The semiconductor apparatus according to Additional Note 7, wherein
at least one third trench is formed in the semiconductor substrate between the first first trench gate and the second first trench gate,
the first first trench gate and one of the plurality of second trench gates are disposed in the third trench,
the at least one third trench reaches the drift layer,
the at least one third trench is larger in depth from the first surface than each of the plurality of second trench gates is, and
an insulating film is buried in the at least one third trench below the plurality of second trench gates.

### Additional Note 9

The semiconductor apparatus according to any one of Additional Notes 1 to 8, wherein
the at least one first trench gate is disposed in at least one first trench formed in the semiconductor substrate at the first surface,
the plurality of second trench gates are disposed in a plurality of second trenches formed in the semiconductor substrate at the first surface, and
the plurality of second trenches each have an opening smaller in width than an opening that the at least one first trench has.

### Additional Note 10

The semiconductor apparatus according to any one of Additional Notes 1 to 9, further comprising a drive circuit to control a switching operation of the bipolar transistor, wherein
the drive circuit is capable of applying different voltages to the at least one first trench gate and the plurality of second trench gates,
when the bipolar transistor is in a steady off state, an off voltage is applied to the at least one first trench gate and a first voltage smaller than a threshold voltage of the second trench gate is applied to each of the plurality of second trench gates, and
when the bipolar transistor is in a steady on state, an on voltage is applied to the at least one first trench gate and a second voltage larger than the threshold voltage is applied to each of the plurality of second trench gates.

### Additional Note 11

The semiconductor apparatus according to Additional Note 10, wherein the drive circuit is capable of applying different voltages to the at least one first trench gate and the plurality of second trench gates with different timings during the switching operation of the bipolar transistor.

### Additional Note 12

The semiconductor apparatus according to Additional Note 11, wherein
in turning off the bipolar transistor, the first voltage is applied to each of the plurality of second trench gates, and thereafter the off voltage is applied to the at least one first trench gate, and
in turning on the bipolar transistor, the second voltage is applied to each of the plurality of second trench gates, and thereafter the on voltage is applied to the at least one first trench gate.

### Additional Note 13

The semiconductor apparatus according to Additional Note 12, wherein
the drive circuit includes a second turn-off circuit and a second turn-on circuit electrically connected to each of the plurality of second trench gates, and
in turning off the bipolar transistor, a first time difference t_{off1} is present after a voltage applied to the plurality of second trench gates changes from the second voltage before a voltage applied to the at least one first trench gate changes from the on voltage, and in turning on the bipolar transistor, a second time difference tₒₙ₁ is present after a voltage applied to the plurality of second trench gates changes from the first voltage before a voltage applied to the at least one first trench gate changes from the off voltage, the first time difference t_{off1} and the second time difference tₒₙ₁ satisfying the above-indicated relational expressions (2) and (3), respectively, where Cᵢₑₛ₂ represents an input capacitance of the plurality of second trench gates, V_{dep-} represents the first voltage, V_{dep+} represents the second voltage, R_{Goff2} represents a gate resistance of the second turn-off circuit, R_{Gon2} represents a gate resistance of the second turn-on circuit, and α represents an arbitrary coefficient larger than 0 and smaller than 1 (0<α<1).

### Additional Note 14

The semiconductor apparatus according to Additional Note 11, wherein
in turning off the bipolar transistor, a third voltage smaller than the first voltage is applied to each of the plurality of second trench gates and thereafter the first voltage is applied thereto, and after the third voltage is applied to each of the plurality of second trench gates before the first voltage is applied thereto the off voltage is applied to the at least one first trench gate, and
in turning on the bipolar transistor, a fourth voltage larger than the second voltage is applied to each of the plurality of second trench gates and thereafter the second voltage is applied thereto, and after the fourth voltage is applied to each of the plurality of second trench gates before the second voltage is applied thereto the on voltage is applied to the at least one first trench gate.

### Additional Note 15

The semiconductor apparatus according to Additional Note 14, wherein
the drive circuit includes a first turn-off circuit and a first turn-on circuit electrically connected to the at least one first trench gate, and a second turn-off circuit and a second turn-on circuit electrically connected to each of the plurality of second trench gates,
in turning off the bipolar transistor, a first time difference t_{off1} is present after a voltage applied to the plurality of second trench gates changes from the second voltage before a voltage applied to the at least one first trench gate changes from the on voltage, and a third time difference t_{off2} is present after the voltage applied to the at least one first trench gate changes from the on voltage before a voltage applied to the plurality of second trench gates changes from the third voltage,
in turning on the bipolar transistor, a second time difference tₒₙ₁ is present after a voltage applied to the plurality of second trench gates changes from the first voltage before a voltage applied to the at least one first trench gate changes from the off voltage, and a fourth time difference tₒₙ₂ is present after the voltage applied to the at least one first trench gate changes from the off voltage before a voltage applied to the plurality of second trench gates changes from the fourth voltage, the first time difference t_{off1}, the second time difference tₒₙ₁, the third time difference t_{off2}, and the fourth time difference tₒₙ₂ satisfying the above-indicated relational expressions (2), (3), (4), and (5), respectively, where Cᵢₑₛ₂ represents an input capacitance of the plurality of second trench gates, V_{dep-} represents the first voltage, V_{dep+} represents the second voltage, R_{Goff2} represents a gate resistance of the second turn-off circuit, R_{Gon2} represents a gate resistance of the second turn-on circuit, and α represents an arbitrary coefficient larger than 0 and smaller than 1 (0<α<1), and furthermore,
C_{iesACT} represents an input capacitance of the at least one first trench gate, C_{resACT} represents a feedback capacitance of the at least one first trench gate, R_{GoffACT} represents a gate resistance of the first turn-off circuit, R_{GonACT} represents a gate resistance of the first turn-on circuit, V_{G-} represents the off voltage, V_{G+} represents the on voltage, V_{Cpeak} represents a peak voltage applied to the bipolar transistor between a collector and an emitter, V_{CEsat} represents a saturation voltage applied to the bipolar transistor between the collector and the emitter, V_{Gplateau} represents a mirror voltage of the bipolar transistor, and tₚ represents a width of a pulse of a voltage applied to the at least one first trench gate.

### Additional Note 16

A method for manufacturing a semiconductor apparatus comprising a bipolar transistor, the method comprising:
a step of preparing a semiconductor substrate having a first surface and being of a first conduction type; and
a first step of forming a body layer of a second conduction type different from the first conduction type, a charge accumulation region of the first conduction type, and a first region of the first conduction type or the second conduction type in the semiconductor substrate on a side closer to the first surface,
in the first step, the first region being formed on a portion of the body layer, the charge accumulation region being formed on a remainder of the body layer.

### Additional Note 17

The method for manufacturing a semiconductor apparatus according to Additional Note 16, wherein
the first region is of the second conduction type,
in the first step, a channel doped layer of the second conduction type is further formed on a side closer to the first surface than the charge accumulation region is,
the first step includes:
   a first implantation step of implanting impurity ions of the first conduction type into the semiconductor substrate through a first mask to form a first implantation region;
   after the first implantation step, a second implantation step of implanting impurity ions of the second conduction type through a second mask different from the first mask to form a second implantation region; and
   after the second implantation step, a step of heating the semiconductor substrate for diffusion,
the first mask has a first opening that opens on a region in which the charge accumulation region is to be formed, and the first mask covers a region in which the first region is to be formed,
the second mask has a second opening that is larger than the first opening and opens on a portion of the region in which the first region is to be formed, and the second mask covers a remainder of the region in which the first region is to be formed, and
by the first step, the charge accumulation region is formed from the first implantation region, and the first region and the channel doped layer are formed from the second implantation region.

### Additional Note 18

The method for manufacturing a semiconductor apparatus according to Additional Note 16, wherein
the first region is of the second conduction type,
in the first step, a channel doped layer of the second conduction type is further formed on a side closer to the first surface than the charge accumulation region is,
the first step includes:
   a first implantation step of implanting impurity ions of the first conduction type into the semiconductor substrate through a first mask to form a first implantation region;
   after the first implantation step, a third implantation step of implanting impurity ions of the second conduction type to form a third implantation region; and
   after the third implantation step, a step of heating the semiconductor substrate for diffusion,
the first mask has a first opening that opens on a region in which the charge accumulation region is to be formed, and the first mask covers a region in which the first region is to be formed, and
by the first step, the charge accumulation region is formed from the first implantation region, and the first region and the channel doped layer are formed from the third implantation region.

### Additional Note 19

The method for manufacturing a semiconductor apparatus according to Additional Note 16, wherein
the first region is of the first conduction type,
in the first step, a channel doped layer of the second conduction type is further formed on a side closer to the first surface than the charge accumulation region is,
the first step includes:
   a fourth implantation step of implanting impurity ions of the first conduction type into the semiconductor substrate through a third mask to form a fourth implantation region;
   after the fourth implantation step, a fifth implantation step of implanting impurity ions of the second conduction type through a fourth mask different from the third mask to form a fifth implantation region; and
   after the fifth implantation step, a step of heating the semiconductor substrate for diffusion,
the third mask has a third opening that opens on a region in which the charge accumulation region is to be formed and on a portion of a region in which the first region is to be formed,
the fourth mask has a fourth opening smaller than the third opening and is formed to cover entirely the region in which the first region is to be formed, and
by the first step, the charge accumulation region and the first region are formed from the fourth implantation region, and the channel doped layer is formed from the fifth implantation region.

### Additional Note 20

The method for manufacturing a semiconductor apparatus according to any one of Additional Notes 16 to 19, further comprising, after the first step, a second step of forming at least one first trench and a plurality of second trenches extending from the first surface toward a second surface located on a side opposite to the first surface, wherein
in the second step, the semiconductor substrate is selectively etched on a side of the first surface through a trench mask having a fifth opening that opens on a region in which the at least one first trench is to be formed and a plurality of sixth openings that open on a region in which the plurality of second trenches are to be formed, and
each sixth opening is smaller in width than the fifth opening.

Although the embodiments of the present invention have been described, it should be understood that the embodiments disclosed herein are illustrative and non-restrictive in all respects. The scope of the present invention is defined by the appended claims, and all changes which come within the meaning and range of equivalency of the claims are intended to be embraced therein.

What is claimed is:

1. A semiconductor apparatus comprising a bipolar transistor, comprising:
a semiconductor substrate having a first surface and a second surface opposite to the first surface;
at least one first trench gate and a plurality of second trench gates extending from the first surface of the semiconductor substrate toward the second surface of the semiconductor substrate; and
a first electrode provided on the first surface,
the semiconductor substrate including:
a drift layer;
a body layer located closer to the first surface than the drift layer is;
a charge accumulation region located on the body layer; and
a source region and a contact region formed in the first surface and electrically connected to the first electrode,
the plurality of second trench gates being each smaller in depth from the first surface than the at least one first trench gate is,
the at least one first trench gate penetrating the source region, the charge accumulation region, and the body layer to reach the drift layer,
the plurality of second trench gates being spaced from and adjacent to one another,
between adjacent ones of the plurality of second trench gates, the semiconductor substrate including the body layer, the contact region, and a first region located between the body layer and the contact region and having an impurity density lower than that of the body layer.

2. The semiconductor apparatus according to claim 1, wherein the first region has the impurity density in a profile having a local minimum in a direction intersecting the first surface.

3. The semiconductor apparatus according to claim 1, wherein the semiconductor substrate between adjacent ones of the plurality of second trench gates further includes a channel doped layer located between the contact region and the first region and having an impurity density higher than that of the body layer.

4. The semiconducting apparatus according to claim 1, wherein
the plurality of second trench gates are disposed in a plurality of second trenches formed in the semiconductor substrate at the first surface,
the first region is of a conduction type identical to that of the body layer, and
the plurality of second trenches have a spacing Wp therebetween satisfying the following relational expression (1):
$${W}_{p} < {\{ \frac{16 ε {k}_{B} T}{{q}^{2} {N}_{A}} ln ( \frac{{N}_{A}}{{n}_{i}} ) \}}^{\frac{1}{2}} , \qquad ( 1 )$$
where Wp represents the spacing between the plurality of second trenches, N_{A} represents the impurity density of the first region, nᵢ represents an intrinsic carrier density of a semiconductor material forming the first region, ε represents a dielectric constant of the semiconductor material forming the first region, k_{B} represents a Boltzmann coefficient, T represents an absolute temperature, and q represents an elementary charge.

5. The semiconductor apparatus according to claim 4, wherein
the at least one first trench gate is a plurality of first trench gates spaced from one another, and
the plurality of second trench gates are three or more second trench gates disposed between the plurality of first trench gates and are formed in three or more second trenches formed in the semiconductor substrate.

6. The semiconductor apparatus according to claim 1, wherein the at least one first trench gate includes: a plurality of electrode portions that are disposed in at least one first trench formed in the semiconductor substrate at the first surface and are spaced from one another in a direction intersecting the first surface; and an insulating film that covers the plurality of electrode portions in the at least one first trench.

7. The semiconductor apparatus according to claim 1, wherein
the at least one first trench gate has a first first trench gate, a second first trench gate provided on one side with respect to the first first trench gate, and a third first trench gate provided on a side opposite to the second first trench gate with respect to the first first trench gate,
a spacing between the first first trench gate and the second first trench gate is larger than a spacing between the first first trench gate and the third first trench gate,
the plurality of second trench gates are only disposed between the first first trench gate and the second first trench gate, and
between the first first trench gate and the second first trench gate the contact region is only disposed between the plurality of second trench gates.

8. The semiconductor apparatus according to claim 7, wherein
at least one third trench is formed in the semiconductor substrate between the first first trench gate and the second first trench gate,
the first first trench gate and one of the plurality of second trench gates are disposed in the third trench,
the at least one third trench reaches the drift layer,
the at least one third trench is larger in depth from the first surface than each of the plurality of second trench gates is, and
an insulating film is buried in the at least one third trench below the plurality of second trench gates.

9. The semiconductor apparatus according to claim 1, wherein
the at least one first trench gate is disposed in at least one first trench formed in the semiconductor substrate at the first surface,
the plurality of second trench gates are disposed in a plurality of second trenches formed in the semiconductor substrate at the first surface, and
the plurality of second trenches each have an opening smaller in width than an opening that the at least one first trench has.

10. The semiconductor apparatus according to claim 1, further comprising a drive circuit to control a switching operation of the bipolar transistor, wherein
the drive circuit is capable of applying different voltages to the at least one first trench gate and the plurality of second trench gates,
when the bipolar transistor is in a steady off state, an off voltage is applied to the at least one first trench gate and a first voltage smaller than a threshold voltage of the plurality of second trench gates is applied to each of the plurality of second trench gates, and
when the bipolar transistor is in a steady on state, an on voltage is applied to the at least one first trench gate and a second voltage larger than the threshold voltage is applied to each of the plurality of second trench gates.

11. The semiconductor apparatus according to claim 10, wherein the drive circuit is capable of applying different voltages to the at least one first trench gate and the plurality of second trench gates with different timings during the switching operation of the bipolar transistor.

12. The semiconductor apparatus according to claim 11, wherein
in turning off the bipolar transistor, the first voltage is applied to each of the plurality of second trench gates, and thereafter the off voltage is applied to the at least one first trench gate, and
in turning on the bipolar transistor, the second voltage is applied to each of the plurality of second trench gates, and thereafter the on voltage is applied to the at least one first trench gate.

13. The semiconductor apparatus according to claim 12, wherein
the drive circuit includes a second turn-off circuit and a second turn-on circuit electrically connected to each of the plurality of second trench gates, and
in turning off the bipolar transistor, a first time difference t_{off1} is present after a voltage applied to the plurality of second trench gates changes from the second voltage before a voltage applied to the at least one first trench gate changes from the on voltage, and in turning on the bipolar transistor, a second time difference tₒₙ₁ is present after a voltage applied to the plurality of second trench gates changes from the first voltage before a voltage applied to the at least one first trench gate changes from the off voltage, the first time difference t_{off1} and the second time difference tₒₙ₁ satisfying the following relational expressions (2) and (3):
$${t}_{off 1} > {C}_{i e s 2} {R}_{Goff 2} ln [ \frac{{V}_{dep +} - {V}_{dep -}}{{V}_{dep -} ( 1 - α )} ] and \qquad ( 2 )$$
$${t}_{on 1} > {C}_{i e s 2} {R}_{Gon 2} ln [ \frac{{V}_{dep +} - {V}_{dep -}}{{V}_{dep +} ( 1 - α )} ] , \qquad ( 3 )$$
respectively, where Cᵢₑₛ₂ represents an input capacitance of the plurality of second trench gates, V_{dep-} represents the first voltage, V_{dep+} represents the second voltage, R_{Goff2} represents a gate resistance of the second turn-off circuit, R_{Gon2} represents a gate resistance of the second turn-on circuit, and α represents an arbitrary coefficient larger than 0 and smaller than 1 (0<α<1).

14. The semiconductor apparatus according to claim 11, wherein
in turning off the bipolar transistor, a third voltage smaller than the first voltage is applied to each of the plurality of second trench gates and thereafter the first voltage is applied thereto, and after the third voltage is applied to each of the plurality of second trench gates before the first voltage is applied thereto the off voltage is applied to the at least one first trench gate, and
in turning on the bipolar transistor, a fourth voltage larger than the second voltage is applied to each of the plurality of second trench gates and thereafter the second voltage is applied thereto, and after the fourth voltage is applied to each of the plurality of second trench gates before the second voltage is applied thereto the on voltage is applied to the at least one first trench gate.

15. The semiconductor apparatus according to claim 14, wherein
the drive circuit includes a first turn-off circuit and a first turn-on circuit electrically connected to the at least one first trench gate, and a second turn-off circuit and a second turn-on circuit electrically connected to each of the plurality of second trench gates,
in turning off the bipolar transistor, a first time difference t_{off1} is present after a voltage applied to the plurality of second trench gates changes from the second voltage before a voltage applied to the at least one first trench gate changes from the on voltage, and a third time difference t_{off2} is present after the voltage applied to the at least one first trench gate changes from the on voltage before a voltage applied to the plurality of second trench gates changes from the third voltage,
in turning on the bipolar transistor, a second time difference tₒₙ₁ is present after a voltage applied to the plurality of second trench gates changes from the first voltage before a voltage applied to the at least one first trench gate changes from the off voltage, and a fourth time difference tₒₙ₂ is present after the voltage applied to the at least one first trench gate changes from the off voltage before a voltage applied to the plurality of second trench gates changes from the fourth voltage, the first time difference t_{off1}, the second time difference tₒₙ₁, the third time difference t_{off2}, and the fourth time difference tₒₙ₂ satisfying the following relational expressions (2), (3), (4), and (5):
$${t}_{off 1} > {C}_{i e s 2} {R}_{Goff 2} ln [ \frac{{V}_{dep +} - {V}_{dep -}}{{V}_{dep -} ( 1 - α )} ] , \qquad ( 2 )$$
$${t}_{on 1} > {C}_{i e s 2} {R}_{Gon 2} ln [ \frac{{V}_{dep +} - {V}_{dep -}}{{V}_{dep +} ( 1 - α )} ] , \qquad ( 3 )$$
$${t}_{off 2} > {R}_{GoffAct} {C}_{iesAct} ln [ \frac{1}{{V}_{G -} ( 1 - α )} \{ ( {V}_{G +} - {V}_{G -} ) ( exp [ - \frac{{t}_{p}}{{R}_{GoffAct} {C}_{iesAct}} ] - 1 ) \} ] + {R}_{GoffAct} {C}_{iesAct} \frac{{V}_{Cpeak} - {V}_{CEsat}}{{V}_{Gplateau}} , and \qquad ( 4 )$$
$${t}_{on 2} > {C}_{iesAct} {R}_{GonAct} ln [ \frac{{V}_{G +} - {V}_{G -}}{{V}_{G +} ( 1 - α )} ] + \frac{{R}_{GonAct} {C}_{resAct}}{{V}_{G +} - {V}_{Gplateau}} [ {V}_{CC} - {V}_{CEsat} ] . \qquad ( 5 )$$
respectively, where Cᵢₑₛ₂ represents an input capacitance of the plurality of second trench gates, V_{dep-} represents the first voltage, V_{dep+} represents the second voltage, R_{Goff2} represents a gate resistance of the second turn-off circuit, R_{Gon2} represents a gate resistance of the second turn-on circuit, and α represents an arbitrary coefficient larger than 0 and smaller than 1 (0<α<1), and furthermore,
C_{iesACT} represents an input capacitance of the at least one first trench gate, C_{resACT} represents a feedback capacitance of the at least one first trench gate, R_{GoffACT} represents a gate resistance of the first turn-off circuit, R_{GonACT} represents a gate resistance of the first turn-on circuit, V_{G-} represents the off voltage, V_{G+} represents the on voltage, V_{Cpeak} represents a peak voltage applied to the bipolar transistor between a collector and an emitter, V_{CEsat} represents a saturation voltage applied to the bipolar transistor between the collector and the emitter, V_{Gplateau} represents a mirror voltage of the bipolar transistor, and tₚ represents a width of a pulse of a voltage applied to the at least one first trench gate.

16. A method for manufacturing a semiconductor apparatus comprising a bipolar transistor, the method comprising:
a step of preparing a semiconductor substrate having a first surface and being of a first conduction type; and
a first step of forming a body layer of a second conduction type different from the first conduction type, a charge accumulation region of the first conduction type, and a first region of the first conduction type or the second conduction type in the semiconductor substrate on a side closer to the first surface,
in the first step, the first region being formed on a portion of the body layer, the charge accumulation region being formed on a remainder of the body layer.

17. The method for manufacturing a semiconductor apparatus according to claim 16, wherein
the first region is of the second conduction type,
in the first step, a channel doped layer of the second conduction type is further formed on a side closer to the first surface than the charge accumulation region is,
the first step includes:
a first implantation step of implanting impurity ions of the first conduction type into the semiconductor substrate through a first mask to form a first implantation region;
after the first implantation step, a second implantation step of implanting impurity ions of the second conduction type through a second mask different from the first mask to form a second implantation region; and
after the second implantation step, a step of heating the semiconductor substrate for diffusion,
the first mask has a first opening that opens on a region in which the charge accumulation region is to be formed, and the first mask covers a region in which the first region is to be formed,
the second mask has a second opening that is larger than the first opening and opens on a portion of the region in which the first region is to be formed, and the second mask covers a remainder of the region in which the first region is to be formed, and
by the first step, the charge accumulation region is formed from the first implantation region, and the first region and the channel doped layer are formed from the second implantation region.

18. The method for manufacturing a semiconductor apparatus according to claim 16, wherein
the first region is of the second conduction type,
in the first step, a channel doped layer of the second conduction type is further formed on a side closer to the first surface than the charge accumulation region is,
the first step includes:
a first implantation step of implanting impurity ions of the first conduction type into the semiconductor substrate through a first mask to form a first implantation region;
after the first implantation step, a third implantation step of implanting impurity ions of the second conduction type to form a third implantation region; and
after the third implantation step, a step of heating the semiconductor substrate for diffusion,
the first mask has a first opening that opens on a region in which the charge accumulation region is to be formed, and the first mask covers a region in which the first region is to be formed, and
by the first step, the charge accumulation region is formed from the first implantation region, and the first region and the channel doped layer are formed from the third implantation region.

19. The method for manufacturing a semiconductor apparatus according to claim 16, wherein
the first region is of the first conduction type,
in the first step, a channel doped layer of the second conduction type is further formed on a side closer to the first surface than the charge accumulation region is,
the first step includes:
a fourth implantation step of implanting impurity ions of the first conduction type into the semiconductor substrate through a third mask to form a fourth implantation region;
after the fourth implantation step, a fifth implantation step of implanting impurity ions of the second conduction type through a fourth mask different from the third mask to form a fifth implantation region; and
after the fifth implantation step, a step of heating the semiconductor substrate for diffusion,
the third mask has a third opening that opens on a region in which the charge accumulation region is to be formed and on a portion of a region in which the first region is to be formed,
the fourth mask has a fourth opening smaller than the third opening and is formed to cover entirely the region in which the first region is to be formed, and
by the first step, the charge accumulation region and the first region are formed from the fourth implantation region, and the channel doped layer is formed from the fifth implantation region.

20. The method for manufacturing a semiconductor apparatus according to claim 16, further comprising, after the first step, a second step of forming at least one first trench and a plurality of second trenches extending from the first surface toward a second surface located on a side opposite to the first surface, wherein
in the second step, the semiconductor substrate is selectively etched on a side of the first surface through a trench mask having a fifth opening that opens on a region in which the at least one first trench is to be formed and a plurality of sixth openings that open on a region in which the plurality of second trenches are to be formed, and
the sixth opening is smaller in width than the fifth opening.
